(19) United States
(12) Patent Application Publication
(10) Pub. No.: US 2024/0066658 A1
(43) Pub. Date: Feb. 29, 2024

(54) POLISHING HEAD SYSTEM AND POLISHING METHOD

(71) Applicant: EBARA CORPORATION, Tokyo (JP)

(72) Inventor: Osamu NABEYA, Tokyo (JP)

(21) Appl. No.: 18/237,263

(22) Filed: Aug. 23, 2023

(30) Foreign Application Priority Data
Aug. 31, 2022 (JP) 2022-137958
Apr. 19, 2023 (JP) 2023-068317

(51) Int. Cl. B24B 37/005; B24B 37/04; B24B 37/32

(52) U.S. Cl. CPC B24B 37/005; B24B 37/042; B24B 37/32

(57) ABSTRACT

A polishing-head system capable of precisely controlling a polishing rate for a substrate, such as a wafer, and more particularly a polishing rate at an edge portion is disclosed. The polishing-head system includes a polishing head, a head shaft, a head rotating mechanism, a multi-path rotary joint, a fluid supply line, and a pressure regulator, wherein the polishing head has a substrate pressing surface, a retainer ring, and pressure chambers arranged along a circumferential direction of the retainer ring, the head shaft has shaft flow-passages communicating with the pressure chambers, respectively, and the multi-path rotary joint is configured to sequentially provide a communication between the fluid supply line and the shall flow-passages each time the head shaft makes one revolution.

### CROSS REFERENCE TO RELATED APPLICATION

This document claims priorities to Japanese Patent Application No. 2022-137958 filed Aug. 31, 2022, and Japanese Patent Application No. 2023-068317 filed Apr. 19, 2023, the entire contents of which are hereby incorporated by reference.

### BACKGROUND

With a recent trend toward higher integration and higher density in semiconductor devices, circuit interconnects become finer and finer and the number of levels in multilayer interconnect is increasing. In the process of achieving the multilayer interconnect structure with finer interconnects, film coverage of step geometry (or step coverage) is lowered through thin film formation as the number of interconnect levels increases, because surface steps grow while following surface irregularities on a lower laver. Therefore, in order to fabricate the multilayer interconnect structure, it is necessary to improve the step coverage and planarize the surface in an appropriate process. Further, since finer optical lithography entails shallower depth of focus, it is necessary to planarize surfaces of semiconductor device so that irregularity steps formed thereon fall within a depth of focus in optical lithography.

Accordingly, in a manufacturing process of the semiconductor devices, a planarization technique for a surface of the semiconductor device is becoming more important. The most important technique in this planarization technique for the surface is chemical mechanical polishing (CMP). This chemical mechanical polishing (which will be hereinafter called CMP) is a process of polishing a substrate, such as a wafer, by placing the substrate in sliding contact with a polishing surface of a polishing pad while supplying a polishing liquid containing abrasive grains, such as silica (SiO₂) (e.g., shiny containing abrasive grains), onto the polishing surface of the polishing pad.

A polishing apparatus for performing CMP includes a polishing table configured to support a polishing pad having a polishing surface, and a polishing head (substrate holding device) for holding a substrate. Polishing of a substrate with such a polishing apparatus is performed as follows. A polishing liquid is supplied onto the polishing pad while the polishing table is rotated together with the polishing pad. The polishing head presses the substrate against the polishing surface of the polishing pad while rotating the substrate. The substrate is in sliding contact with the polishing pad in the presence of the polishing liquid, so that a surface of the substrate is planarized by a combination of a chemical action of the polishing liquid and mechanical action(s) of abrasive grains contained in the polishing liquid and/or the polishing pad.

If a relative pressing force between the substrate and the polishing surface of the polishing pad during polishing is not uniform over the entire surface of the substrate, lack of polishing or excessive polishing may occur according to the pressing force applied to each portion of the substrate. Thus, in order to make the pressing force on the substrate uniform, a pressure chamber formed in an elastic membrane has been provided at a lower portion of the polishing head. Fluid, such as air, is supplied into this pressure chamber to press the substrate with fluid pressure applied through the elastic membrane.

Since the polishing pad has elasticity, the pressing force applied to an edge portion (i.e., a periphery) of the substrate during polishing may become non-uniform. As a result, so-called “dull edge”, in which only the edge portion of the substrate is polished excessively, may occur. In order to prevent such dull edge and to prevent the substrate from slipping out of the polishing head during polishing, a polishing head including a retainer ring has been used. This retainer ring is arranged so as to surround the substrate, and during polishing of the substrate, the retainer ring presses the polishing pad outside the substrate while the retainer ring is rotating.

In recent years, types of semiconductor devices have increased dramatically, so that there is an increasing need to adjust a polishing rate at the edge portion of the substrate for each device or each CMP process (e.g., oxide film polishing, metal film polishing, etc.). One of the reasons for this is that an initial film-thickness distribution of the substrate varies depending on a deposition process, because the deposition process performed before each CMP process varies depending on a type of film. Generally, a substrate after CMP process is required to have a uniform filer-thickness distribution over the entire surface of the substrate. Therefore, it is necessary to adjust the polishing rate according to the initial film-thickness distribution.

Another reason is that types of polishing pads and types of polishing liquids for use in the polishing apparatus are increasing from viewpoints of cost, etc. If the types of consumable materials, such as polishing pads or polishing liquids, differ, the initial film-thickness distribution, particularly at the edge portion of the substrate, may significantly vary. In the manufacturing of the semiconductor devices, it is very important to precisely adjust the polishing rate of the edge portion of the substrate because variations in film thickness at the edge portion of the substrate may greatly affect a yield of a product.

As described above, the polishing head including the retainer ring has conventionally been used. The polishing rate at the edge portion of the substrate can be adjusted by the pressing force applied to this retainer ring. However, when the pressing force applied to the retainer ring is changed, the polishing rate may change over a relatively wide range including not only the edge portion but also other region of the substrate. Therefore, this method has not been suitable when the polishing profile at the edge portion of the substrate is to be precisely controlled.

Japanese laid-open patent publication No. 2014-4675 describes a method of applying a local load to a part of a retainer ring by a local-load applying mechanism. However, in such a local-load applying mechanism, there may be problems, such as necessity to prevent entry of liquid used in the polishing apparatus into the local-load applying mechanism and to prevent generation of particles.

### SUMMARY

The present inventor has conducted various experiments, and as a result, has found that the polishing rate at the edge portion of the substrate can be precisely controlled by changing the pressing force along a circumferential direction of the retainer ring when the pressing force is applied to the retainer ring that retains the edge portion of the substrate.

There are provided a polishing-head system and a polishing method capable of precisely controlling a polishing rate of a substrate (e.g., wafer), more particularly a polishing rate at an edge portion of the substrate.

Embodiments, which will be described below, relate to a polishing-head system and a polishing method for a substrate, such as a wafer.

In an embodiment, there is provided a polishing-head system comprising: a polishing head configured to press a substrate against a polishing surface; a head shaft coupled to the polishing head; a head rotating mechanism configured to rotate the polishing head together with the head shaft; a multi-path rotary joint arranged around at least a part of the head shaft; a fluid supply line coupled to the multi-path rotary joint; and a pressure regulator attached to the fluid supply line, wherein the polishing head has: a substrate pressing surface configured to press the substrate against the polishing surface; a retainer ring arranged around the substrate pressing surface; and pressure chambers formed by elastic material and configured to generate pressing forces for pressing the retainer ring against the polishing surface, the head shaft has shaft flow-passages communicating with the pressure chambers, respectively, the multi-path rotary joint is configured to provide a communication between the fluid supply line and each one of the shaft flow-passages successively each time the head shaft makes one revolution, and the pressure chambers are arranged along a circumferential direction of the retainer ring.

In an embodiment, the shaft flow-passages have shaft openings being open in an outer surface of the head shaft, the multi-path rotary joint has the joint flow-passage communicating with the fluid supply line, the joint flow-passage has a joint opening being open in an inner surface of the multi-path rotary joint, the shaft openings are arranged along a circumferential direction of the head shaft, and the shaft openings and the joint opening are located at the same position in an axial direction of the head shaft.

In an embodiment, the fluid supply line comprises fluid supply lines, the pressure regulator comprises pressure regulators attached to the fluid supply lines, respectively, the joint flow-passage comprises joint flow-passages communicating with the fluid supply lines, respectively, and the joint opening comprises joint openings arranged along the circumferential direction of the head shaft.

In an embodiment, the multi-path rotary joint has: a joint member arranged along a circumferential direction of the head shaft; a joint holder arranged around the joint member; and a spring configured to press the joint member against the heart shaft, and the joint flow-passage extends through the joint member and the joint holder.

In an embodiment, the multi-path rotary joint has a positioning mechanism configured to fix a relative position of the joint member with respect to the joint holder in a circumferential direction of the joint member.

In an embodiment, the pressure chambers comprise pressure chamber groups, the pressure chamber groups communicate with the shaft flow-passages, respectively, and each of the pressure chamber groups includes pressure chambers formed by rolling diaphragms, the rolling diaphragms being arranged along the circumferential direction of the retainer ring.

In an embodiment, each of the rolling diaphragms has a cylindrical shape.

In an embodiment, the polishing head further includes an annular pressure chamber located adjacent to the pressure chambers.

In an embodiment, a width of the joint opening is larger than a width of each of the shaft openings.

In an embodiment, the polishing-head system further comprises an operation controller configured to control an operation of the pressure regulator, Wherein the pressure chambers include a first pressure chamber, the operation controller is configured to transmit a correcting set-pressure-value, which is larger than a set pressure value of fluid in the fluid supply line, to cause the pressure regulator to correct a pressure in the first pressure chamber when the pressure in the first pressure chamber is smaller than a target value.

In an embodiment, the operation controller is configured to determine the correcting set-pressure-value that minimizes a difference between an integral value of the pressure in the first pressure chamber during one revolution of the polishing head and an integral value of the target pressure during one revolution of the polishing head.

In an embodiment, the polishing-head system further comprises a pressure sensor configured to measure the pressure in the first pressure chamber, wherein the operation controller is configured to determine the correcting set-pressure-value that minimizes a difference between the pressure in the first pressure chamber measured by the pressure sensor and the target pressure.

In an embodiment the operation controller is configured to determine the correcting set-pressure-value that minimizes a difference between the pressure in the first pressure chamber and the target pressure based on a correlation, which is obtained in advance, between the set pressure value and the pressure in the first pressure chamber.

In an embodiment, there is provided a polishing method for a substrate pith the above-mentioned polishing-head system, comprising: pressing the substrate against the polishing surface while rotating the substrate to polish the substrate; and during polishing of the substrate, applying pressing forces to the retainer ring to press the retainer ring against the polishing surface by supplying fluid into the pressure chambers through the fluid supply line while providing a communication between the fluid supply line and each one of the shaft flow-passages successively, wherein the pressing forces include at least two different pressing forces.

In an embodiment, polishing of the substrate is performed while rotating the polishing surface, and the polishing method comprises regulating pressures in the pressure chambers by the pressure regulator such that a pressing force generated by a pressure chamber, which is one of the pressure chambers, located at a downstream side in a rotating direction of the polishing surface is larger than a pressing force generated by other pressure chamber.

In an embodiment, the polishing method further comprises causing the pressure regulator to correct a pressure in a first pressure chamber of the pressure chambers based on a correcting set-pressure-value, which is larger than a set pressure value of the fluid in the fluid supply line, when the pressure in the first pressure chamber is smaller than a target pressure.

In an embodiment, the polishing method further comprises determining the correcting set-pressure-value that minimizes a difference between an integral value of the pressure in the first pressure chamber during one revolution of the polishing head and an integral value of the target pressure during one revolution of the polishing head.

In an embodiment, the polishing method further comprises measuring the pressure in the first pressure chamber; and determining the correcting set-pressure-value that minimizes a difference between the pressure in the first pressure chamber measured by the pressure sensor and the target pressure.

In an embodiment, the polishing method further comprises determining the correcting set-pressure-value that minimizes a difference between the pressure in the first pressure chamber and the target pressure based on a correlation, which is obtained in advance, between the set pressure value and the pressure in the first pressure chamber.

According to the above-described embodiments, a polishing rate at an edge portion of the substrate can be precisely controlled by applying at least two different pressing forces along the circumferential direction of the retainer ring using the multi-path rotary joint.

### BRIEF DESCRIPTION OF FIE DRAWINGS

FIG. 1 is a schematic diagram showing an embodiment of a polishing apparatus;

FIG. 2 is a cross-sectional view schematically showing an embodiment of a polishing-head system;

FIG. 3 is a plan view showing an embodiment of partition walls and retainer-ring pressing membranes;

FIG. 4 is a plan view schematically showing a multi-path rotary joint;

FIG. 5 is a cross-sectional view taken along line A-A of a rotary joint assembly shown in FIG. 3;

FIG. 6 is a cross-sectional view taken along line B-B of FIG. 5;

FIG. 7 is an exploded view showing an embodiment of the multi-path rotary joint;

FIG. 8 is an enlarged cross-sectional view of the multi-path rotary joint shown in FIG. 7;

FIG. 9 is a cross-sectional view taken along line C-C of FIG. 8;

FIG. 10 is an enlarged cross-sectional view showing an embodiment of a positioning mechanism;

FIG. 11 is a diagram showing a plurality of pressure regions indicating positions where pressing forces generated by a plurality of pressure chambers, respectively, on a pi wittily of regions of a retainer ring are switched;

FIG. 12 is a graph showing an embodiment of change in pressure in one pressure chamber with rotation of a polishing head;

FIG. 13 is a graph showing another embodiment of the change in pressure in the one pressure chamber with the rotation of the polishing head;

FIG. 14 is an exploded view showing another embodiment of the multi-path rotary joint;

FIG. 15 is a cross-sectional view of the multi-path rotary join shown in FIG. 14;

FIG. 16 is a schematic diagram showing another embodiment of the polishing head;

FIG. 17 is a cross-sectional view of a rolling diaphragm shown in FIG. 16;

FIG. 18 is a schematic diagram showing still another embodiment of the polishing head;

FIG. 19 is a cross-sectional view taken along line D-D of a rotary joint assembly shown in FIG. 18;

FIG. 20 is a cross-sectional view of a rolling diaphragm and an annular rolling diaphragm shown in FIG. 18;

FIG. 21 is a graph illustrating difference in change in pressure in one pressure chamber depending on a rotation speed of the polishing head;

FIG. 22 is a cross-sectional view schematically showing another embodiment of the polishing-head system;

FIG. 23 is a graph showing an embodiment of a target pressure, a correcting set-pressure-value to be transmitted to a pressure regulator, and a corrected pressure in one pressure chamber;

FIG. 24 is a diagram illustrating an integral value of the target pressure, and an integral value of the pressure in the pressure chamber; and

FIG. 25 is a graph showing another example of the target pressure, and the correcting set-pressure-value to be transmitted to the pressure regulator.

### DESCRIPTION OF EMBODIMENTS

Hereinafter, embodiments will be described with reference to the drawings.

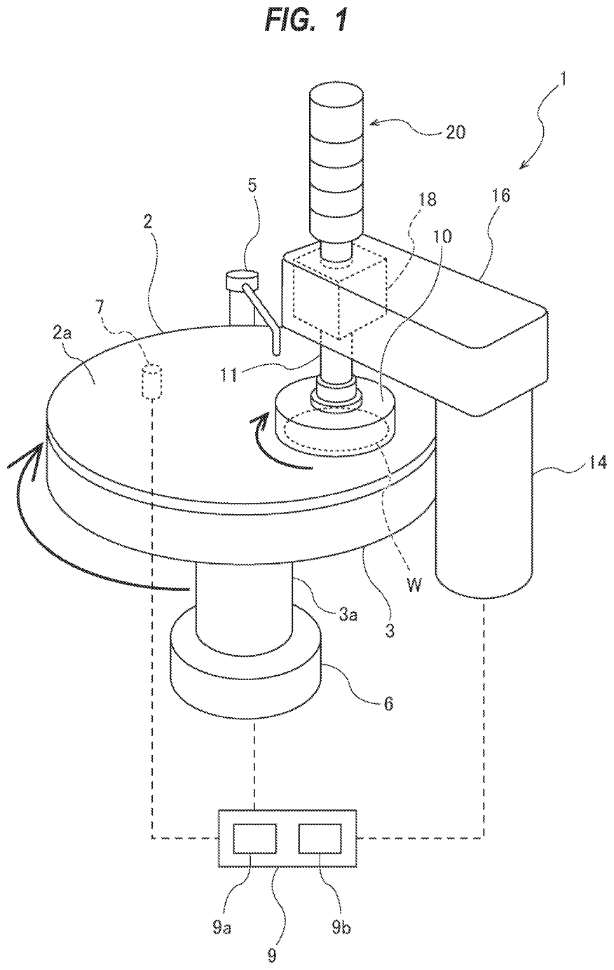

FIG. 1 is a schematic diagram showing an embodiment of a polishing apparatus. The polishing apparatus is a device for polishing a substrate W, such as a wafer. As shown in FIG. 1, the polishing apparatus includes a polishing-head system 1, a polishing table 3 configured to support a polishing pad 2, a polishing-liquid supply nozzle 5 configured to supply a polishing liquid (e.g., slurry containing abrasive grains) onto the polishing pad 2, a table motor 6 configured to rotate the polishing table 3 together with the polishing pad 2, and a film-thickness sensor 7 configured to obtain a film-thickness signal that changes according to a film thickness of the substrate W. The film-thickness sensor 7 is disposed in the polishing table 3, and obtains film-thickness signals at a plurality of regions including a center portion of the substrate W each time the polishing table 3 makes one revolution. Examples of the film-thickness sensor 7 include an optical sensor and an eddy-current sensor,

The polishing pad 2 is attached to an upper surface of the polishing table 3. An exposed surface of the polishing pad 2 constitutes a polishing surface 2a for polishing the substrate W, such as a wafer. The table motor 6 is arranged below the polishing table 3. The polishing, table 3 is coupled to the table motor 6 via a table shaft 3a. The polishing table 3 and the polishing pad 2 are rotated by the table motor 6 around the axis of the table shaft 3a.

The polishing-head system 1 includes a polishing head (substrate holding device) configured to press the substrate W, such as a wafer, against the polishing surface 2a of the polishing pad 2, a head shaft 11 coupled to the polishing head 10, a head oscillation shaft 14, a head oscillation arm 16 coupled to an upper end of the head oscillation shaft 14, and a rotary joint assembly 20 attached to an upper portion of the head shaft 11. The polishing head 10 is fixed to a lower end of the head shaft 11. The polishing head 10 is configured to be able to hold the substrate W on its lower surface. The substrate W is held with its surface to be polished facing downward.

The head shaft 11 is rotatably supported by a free end of the head oscillation arm 16. A head oscillation mechanism (not shown) having an electric motor and other elements is disposed in the head oscillation arm 16. The head oscillation mechanism is coupled to the head oscillation shaft 14. The head oscillation mechanism is configured to oscillate the polishing head 10 together with the head shaft 11 about the axis of the head oscillation shaft 14 via, the head oscillation arm 16.

Further, a head rotating mechanism 18 having an electric motor and other elements is disposed in the head oscillation arm 16. The head rotating mechanism 18 is coupled to the head shaft 11, and is configured to rotate the polishing head 10 together with the head shaft 11 about the axis of the head shaft 11. The head rotating mechanism 18 is constituted of, for example, a combination of a motor, timing pulleys, and a belt. In FIG. 1, the head rotating mechanism 18 is schematically depicted.

The head shaft 11 is coupled to a not-shown head elevating mechanism. This head elevating mechanism is configured to vertically move the head shaft 11 relative to the head oscillation arm 16. The head elevating mechanism is constituted of, for example, a combination of a ball screw and a servomotor. The vertical movement of the head shaft 11 allows the polishing head 10 to move vertically relative to the head oscillation arm 16 and the polishing table 3.

The polishing apparatus further includes an operation controller 9. The polishing-head system 1, the polishing-liquid supply nozzle 5, the table motor 6, and the film-thickness sensor 7 are electrically coupled to the operation controller 9, and operations of the polishing-head system 1, the polishing-liquid supply nozzle 5, the table motor 6, and the film-thickness sensor 7 are controlled by the operation controller 9. In one embodiment, the polishing-head system 1 may include the operation controller 9.

The operation controller 9 is composed of at least one computer. The operation controller 9 includes a memory 9a storing programs therein for controlling the operations of the polishing apparatus, and a processor 9b configured to perform arithmetic operations according to instructions contained in the programs. The memory 9a includes a main memory, such as a random-access memory (RAM), and an auxiliary memory, such as a hard disk drive (HDD) or a solid state drive (SSD). Examples of the processor 9b include a CPU (central processing unit) and a GPU (graphic processing unit). However, the specific configuration of the operation controller 9 is not limited to these examples.

The substrate W is polished as follows. The polishing liquid is supplied from the polishing-liquid supply nozzle 5 onto the polishing surface 2a of the polishing pad 2 placed on the polishing table 3, while the polishing table 3 and polishing head 10 are rotated in directions indicated by arrows in FIG. 1, respectively. The substrate W is pressed against the polishing surface 2a of the polishing pad 2 in the presence of the polishing liquid on the polishing pad 2 while the substrate W is rotated by the polishing head 10. A surface of the substrate W is polished by a chemical action of the polishing liquid and mechanical action(s) of abrasive grains contained in the polishing liquid and/or the polishing pad 2.

During polishing of the substrate W, the film-thickness sensor 7 rotates together with the polishing table 3, and obtains the film-thickness signals while traversing the surface of the substrate W. Each film-thickness signal is an index value that directly or indirectly indicates a film thickness, and changes as the film thickness of the substrate W decreases. The film-thickness sensor 7 is coupled to the operation controller 9, and the film-thickness signals are transmitted to the operation controller 9. When the film thickness of the substrate W indicated by the film-thickness signal reaches a predetermined target value, the operation controller 9 terminates the polishing of the substrate W.

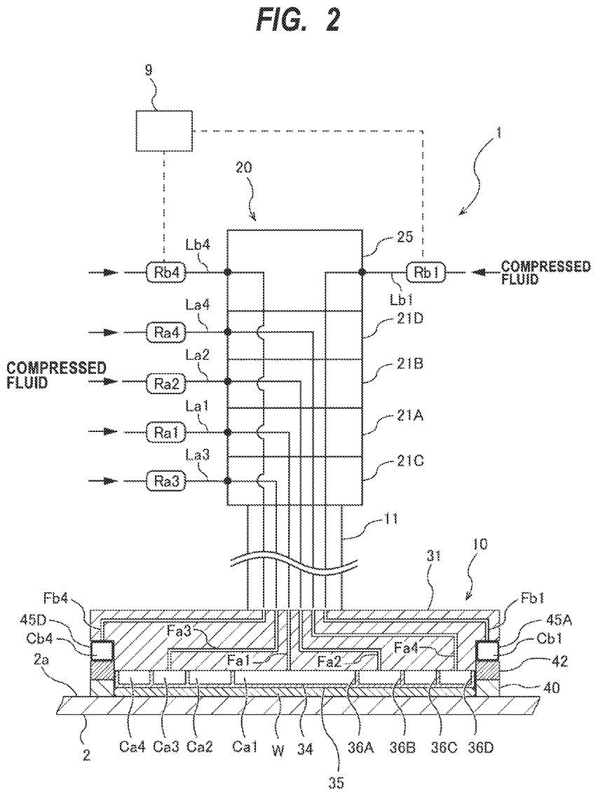

Next, details of configurations of the polishing-head system 1 will be described. FIG. 2 is a cross-sectional view schematically showing an embodiment of the polishing-head system 1. In FIG. 2, depiction of the head oscillation shaft 14, the head oscillation arm 16, and the head rotating mechanism 18 is omitted. As shown in FIG. 2, the polishing head 10 includes a carrier 31 fixed to the end of the head shaft 11, an elastic membrane 34 attached to a lower portion of the carrier 31, a retainer ring 40 arranged so as to surround the substrate W and the elastic membrane 34, and a drive ring 42 fixed to an upper surface of the retainer ring 40.

The elastic membrane 34 has a substrate pressing surface 35 configured to press the substrate W against the polishing surface 2a of the polishing pad 2, and four annular partition walls 36A, 36B, 36C, and 36D extending upward from the substrate pressing surface 35. The substrate pressing surface 35 has substantially the same size and the same shape as those of an upper surface of the substrate W. The partition walls 36A to 36D are endless walls concentrically arranged. Four pressure chambers Ca1, Ca2, Ca3, and Ca4 are formed between the elastic membrane 34 and the carrier 31 by these partition walls 36A to 36D. The elastic membrane 34 is made of elastic material with excellent strength and durability, such as ethylene propylene rubber (EPDM), polyurethane rubber, or silicone rubber.

In this embodiment, the elastic membrane 34 forms the four pressure chambers Ca1 to Ca4, while the present invention is not limited to this embodiment. In one embodiment, the elastic membrane 34 may form less than four pressure chamber(s) or more than four pressure chambers. In other words, in one embodiment, the elastic membrane 34 may have less than four partition wall(s) or more than four partition walls. For example, the elastic membrane 34 may have only one partition wall and may form only one pressure chamber.

The carrier 31, the retainer ring 40, and the drive ring 42 are made of resin, such as engineering plastic (e.g., PEEK). The carrier 31 may be made of metal, such as stainless steel or aluminum. The retainer ring 40 is arranged so as to surround the substrate W and the substrate pressing surface 35 of the elastic membrane 34. The retainer ring 40 is an annular structure configured to retain the substrate W so as to prevent the substrate W from slipping out from the polishing head 10 during polishing of the substrate W.

The drive ring 42 is an annular structure disposed below the carrier 31. The polishing head 10 further includes a plurality of retainer-ring pressing membranes 45A to 45F disposed between the carrier 31 and the drive ring 42. The drive ring 42 is coupled to the plurality of retainer-ring pressing membranes 45A to 45F, The drive ring 42 is located between the retainer ring 40 and the plurality of retainer-ring pressing membranes 45A to 45F.

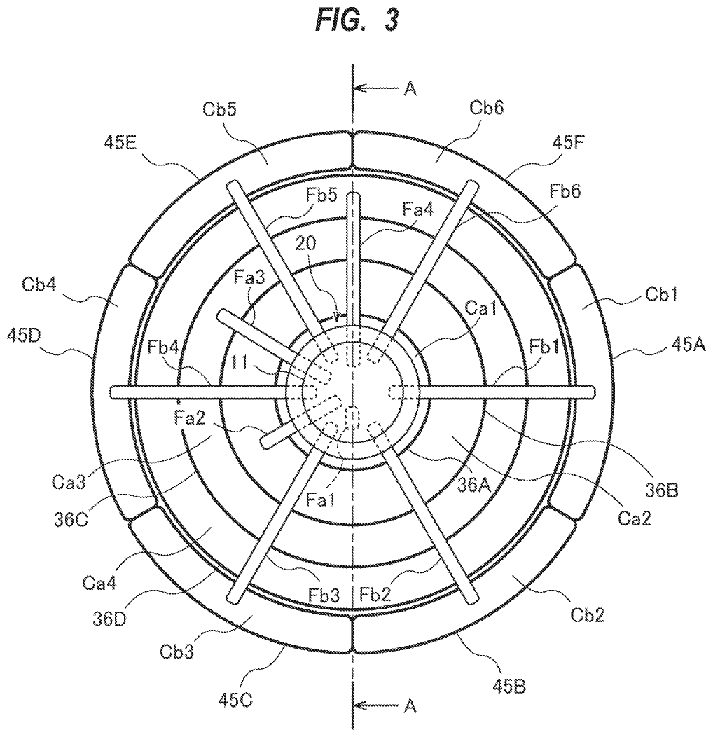

FIG. 3 is a plan view showing an embodiment of the partition walls 36A to 36D and the retainer-ring pressing membranes 45A to 45F. As shown in FIG. 3, in this embodiment, six retainer-ring pressing membranes 45A, 45B, 45C, 45D, 45E, and 45F are arranged along a circumferential direction of the retainer ring 40. Each of the retainer-ring pressing membranes 45A to 45F has an approximately fan-shaped or an arcuate shape when viewed from above. As shown in FIG. 2, each of the retainer-ring pressing membranes 45A to 45F has a rectangular cross section.

Pressure chambers Cb1, Cb2, Cb3, Cb4, Cb5, and Cb6 are formed inside the retainer-ring pressing membranes 45A. 45B, 45C, 45D, 45E, and 45F, respectively. The pressure chambers Cb1 to Cb6 are arranged along the circumferential direction of the retainer ring 40. The retainer-ring pressing membranes 45A to 45F are made of elastic material, such as ethylene propylene rubber (EPDM), polyurethane rubber, or silicone rubber, with excellent strength and durability. In this embodiment, the polishing head 10 has the six retainer-ring pressing membranes 45A to 45F and the six pressure chambers Cb1 to Cb6, while the number of retainer-ring pressing membranes and the number of pressure chambers are not limited to this embodiment. In one embodiment, the polishing head 10 may have less than six or more than six retainer-ring pressing membranes, and may have less than six or more than six pressure chambers.

As shown in FIG. 2, the rotary joint assembly 20 includes four rotary joints 21A, 21B, 21C, and 21D, and a multi-path rotary joint 25. The rotary joints 21A to 21D and the multi-path rotary joint 25 are arranged along an axial direction of the head shaft 11. The pressure Chambers Ca1, Ca2, Ca3, and Ca4 formed by the elastic membrane 34 are coupled to fluid delivery lines Fa1, Fa2, Fa3, and Fa4, respectively. The fluid delivery lines Fa1 to Fa4 extend in the carrier 31 and the head shaft 11, and further extend in the rotary joints 21A to 21D, respectively.

The polishing-head system 1 further includes fluid supply lines La1, La2, La3, and La4 coupled to the rotary joints 21A to 21D, respectively, and pressure regulators Ra1, Ra2, Ra3, and Ra4 attached to the fluid supply lines La1, La2, La3, and La4, respectively. The fluid delivery lines Fa1, Fa2, Fa3, and Fa4 communicate with the fluid supply lines La1, La2, La3, and La4, respectively. One end of each of the fluid supply lines La1 to La4 is coupled to a compressed-fluid supply source (not shown) which may be a utility supply source provided in a factory where the polishing apparatus is installed.

Compressed fluid (e.g., compressed gas, such as compressed air) from the compressed-fluid supply source is independently supplied into the pressure chambers Ca1 to Ca4 through the fluid supply lines La1 to La4 and the fluid delivery lines Fa1 to Fa4, respectively. The pressure regulators Ra1 to Ra4 are configured to independently regulate pressures of the compressed fluid in the pressure chambers Ca1 to Ca4, respectively. The compressed fluid in the pressure chambers Ca1 to Ca4 generates pressing forces for pressing the substrate W against the polishing surface 2a of the polishing pad 2. The pressure regulators Ra1 to Ra4 can independently regulate the pressing forces on four regions of the substrate W against the polishing pad 2 corresponding to positions of the pressure chambers Ca1 to Ca4.

The fluid supply lines La1 to La4 may be coupled to vent valves (not shown), respectively. With this configuration, the pressure chambers Ca1 to Ca4 can communicate with the atmosphere when the vent valves are operated. The pressure regulators Ra1 to Ra4 and the vent valves are coupled to the operation controller 9. The operation controller 9 transmits target pressure values of the pressure chambers Ca1 to Ca4 to the pressure regulators Ra1 to Ra4, which in turn operate such that the pressures in the pressure chambers Ca1 to Ca4 reach corresponding target pressure values, respectively.

The pressure chambers Cb1, Cb2, Cb3, Cb4, Cb5, and Cb6 formed by the retainer-ring pressing membranes 45A to 45F are coupled to fluid delivery lines Fb1, Fb2, Fb3, Fb4, Fb5, and Fb6 (see FIG. 3), respectively. The fluid delivery lines Fb1 to Fb6 extend in the carrier 31, the head shaft 11, and the multi-path rotary joint 25.

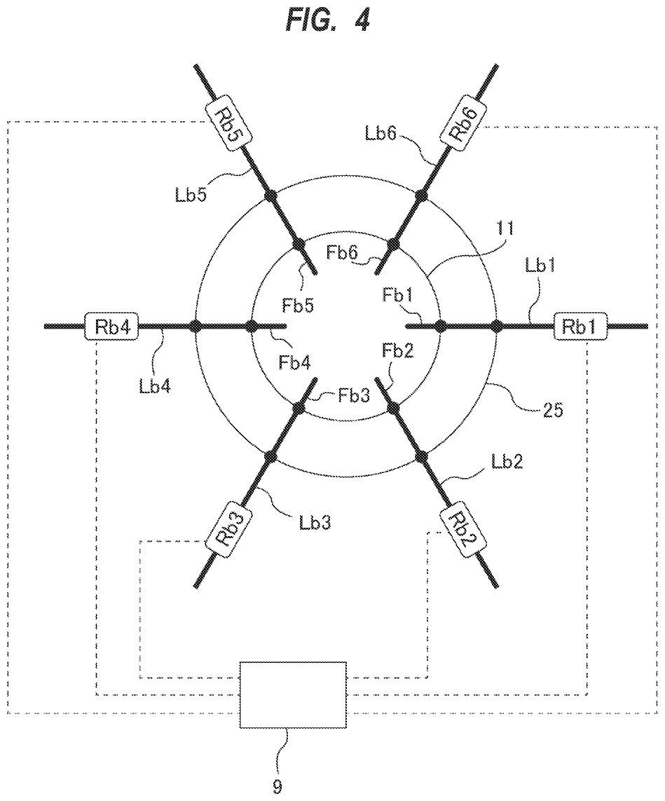

FIG. 4 is a plan view schematically showing the multi-path rotary joint 25, The polishing-head system 1 includes fluid supply lines Lb1, Lb2, Lb3, Lb4, Lb5, and Lb6 coupled to the multi-path rotary joint 25, and further includes pressure regulators Rb1, Rb2, Rb3, Rb4, Rb5, and Rb6 attached to the fluid supply lines Lb1, Lb2, Lb3, Lb4, Lb5, and Lb6, respectively. The fluid delivery lines Fb1, Fb2, Fb3, Fb4, Fb5, and Fb6 communicate with the fluid supply lines Lb1, Lb2, Lb3, Lb4, Lb5, and Lb6, respectively. One end of each of the fluid supply lines Lb1 to Lb6 is coupled to a compressed-fluid supply source (not shown) which may be a utility supply source provided in the factory where the polishing apparatus is installed. In this embodiment, the polishing-head system 1 has the six fluid supply lines Lb1 to Lb6, while the number of fluid supply lines is not limited to this embodiment. In one embodiment, the polishing-head system 1 may have less than six or more than six fluid supply lines.

The multi-path rotary joint 25, whose details will be described later, is configured to switch communications between the fluid supply lines Lb1 to Lb6 and the fluid delivery lines Fb1 to Fb6 one by one with rotation of the head shaft 11. Compressed fluid (e.g., compressed gas, such as compressed air) from the compressed-fluid supply source is independently supplied into the pressure chambers Cb1 to Cb6 through the fluid supply lines Lb1 to Lb6 and the fluid delivery lines Fb1 to Fb6, respectively. The pressure regulators Rb1 to Rb6 are configured to independently regulate pressures of the compressed fluid in the fluid supply lines Lb1 to Lb6, respectively.

The pressures in the pressure chambers Cb1 to Cb6 are regulated to set pressure values of the pressure regulators Rb1 to Rb6 attached to corresponding fluid supply lines Lb1 to Lb6. When the head shaft 11 rotates to switch the fluid supply lines Lb1 to Lb6 from one to another to communicate with the pressure chambers Cb1 to Cb6 successively, the pressures in the pressure Chambers Cb1 to Cb6 are switched from one to another among the set pressure values of the corresponding pressure regulator Rb1 to Rb6. The pressure chambers Cb1 to Cb6 generate pressing forces for pressing six regions of the retainer ring 40 corresponding to positions of the pressure chambers Cb1 to Cb6 against the polishing surface 2a of the polishing pad 2. The pressing forces generated by the pressure chambers Cb1 to Cb6 are applied to the retainer ring 40 via the drive ring 42.

The fluid supply lines Lb1 to Lb6 may be coupled to vent valves (not shown), respectively. With this configuration, the fluid supply lines Lb1 to Lb6 and the pressure chambers Cb1 to Cb6 communicating with the fluid supply lines Lb1 to Lb6 can communicate with the atmosphere when the vent valves are operated. The pressure regulators Rb1 to Rb6 and the vent valves are coupled to the operation controller 9. The operation controller 9 transmits the set pressure values of the compressed fluid in the fluid supply lines Lb1 to Lb6 to the pressure regulators Rb1 to Rb6, respectively, so that the pressure regulators Rb1 to Rb6 operate such that the pressures of the compressed fluid in the fluid supply lines Lb1 to Lb6, i.e., the pressures in the pressure chambers Cb1 to Cb6 communicating with the fluid supply lines Lb1 to Lb6, reach the set pressure values.

The fluid delivery lines Fa1 to Fa4 and the fluid delivery lines Fb1 to Fb6 are arranged at different positions in a circumferential direction of the head shall 11. The positional relationship between the fluid delivery lines Fa1 to Fa4 and the fluid delivery lines Fb1 to Fb6 is not limited to this embodiment as long as the fluid delivery lines Fa1 to Fa4 and the fluid delivery lines Fb1 to Fb6 do not overlap with each other.

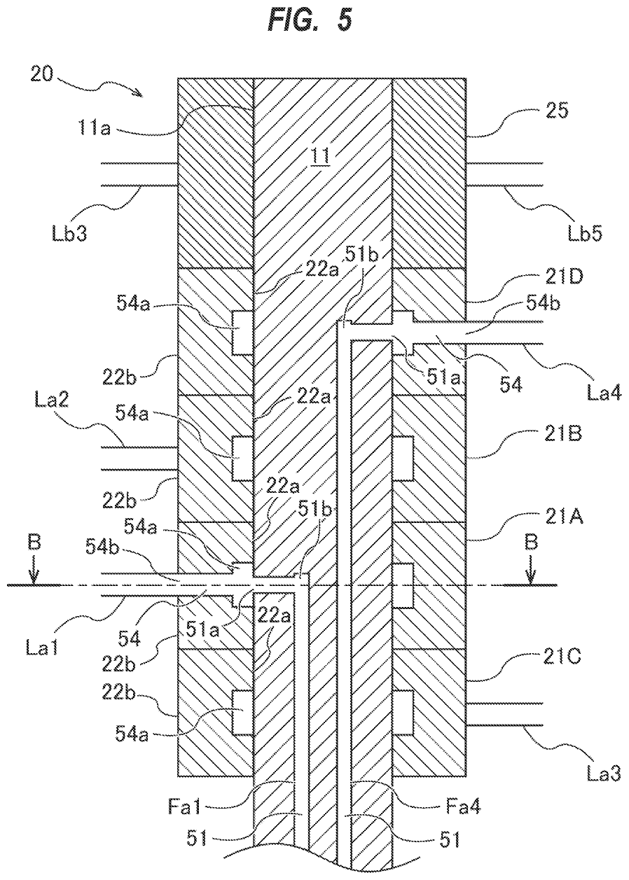

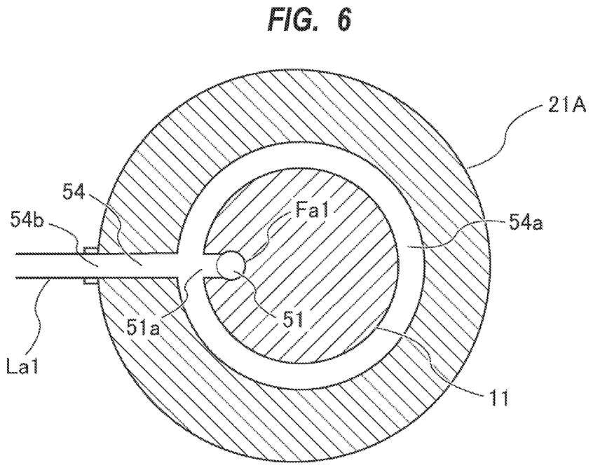

Next, configurations of the rotary joints 21A to 21D will be described. FIG. 5 is a cross-sectional view taken along line A-A of the rotary joint assembly 20 shown in FIG. 3. FIG. 6 is a cross-sectional view taken along the line B-B in FIG. 5. The rotary joints 21A to 21D are arranged so as to surround at least a part of the head shaft 11, and are arranged along the axial direction of the head shaft 11. Configurations of the rotary joints 21A to 21D are basically the same. Therefore, configurations of the rotary joint 21A will be described below. Arrangements of the rotary joints 21A to 21D in the axial direction of the head shaft 11 are not limited to this embodiment.

The fluid delivery line Fa1 has flow passages including a shall flow-passage 51 formed in the head shaft 11 and a joint flow-passage 54 formed in the rotary joint 21A. The shaft flow-passage 51 has a shaft opening 51a being open in an outer surface 11a of the head shaft 11. The shaft flow-passage 51 further has a bent portion 51b. The shaft flow-passage 51 extends upward along the axial direction of the head shaft 11 from the lower end of the head shaft 11, is bent at the bent portion 51b, and extends to the shaft opening 51a. The shaft flow-passage 51 communicates with the pressure chamber Ca1.

The rotary joint 21A has a ring flow-passage 54a, Which is an annular groove formed along a circumferential direction in an inner surface 22a of the rotary joint 21A, and a coupling port 54b being open in an outer surface 22b of the rotary joint 21A. The joint flow-passage 54 communicates with the ring flow-passage 54a and the coupling port 54b. The shaft opening 51a faces the ring flow-passage 54a. The shaft flow-passage 51 and the joint flow-passage 54 communicate with each other through the ring flow-passage 54a. The fluid supply line La1 is coupled to the rotary joint 21A through the coupling port 54b, and communicates with the joint flow-passage 54.

When the head shaft 11 is rotating, the rotary joint 21A and the fluid supply line La1 do not rotate, and their positions are fixed (i.e., remain stationary). When the head shaft 11 rotates together with the polishing head 10, the shaft opening 51a moves in the circumferential direction along the ring flow-passage 54a, so that the fluid supply line La1 communicates with the fluid delivery line Fa1 at all tunes. Therefore, during rotating of the head shaft 11, the compressed fluid is continuously supplied into the pressure chamber Ca1 through the fluid supply line La1 and the fluid delivery line Fa1.

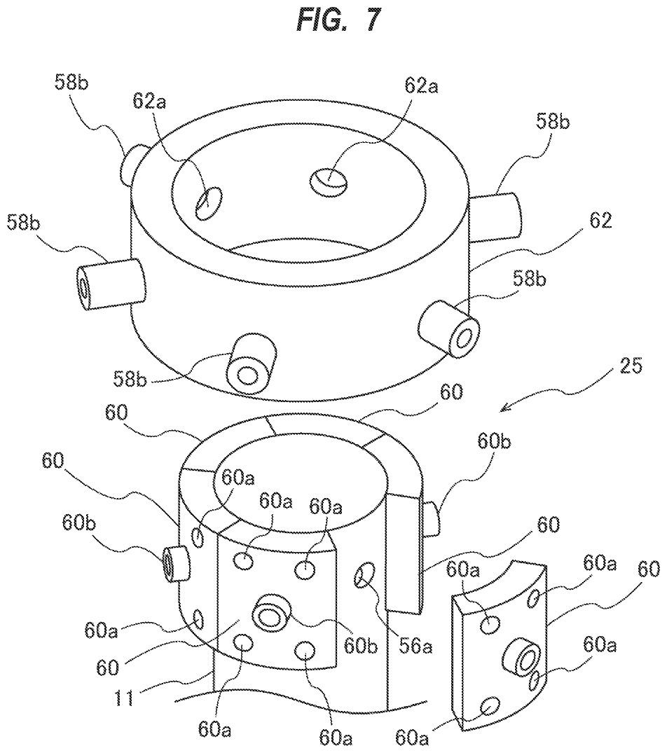

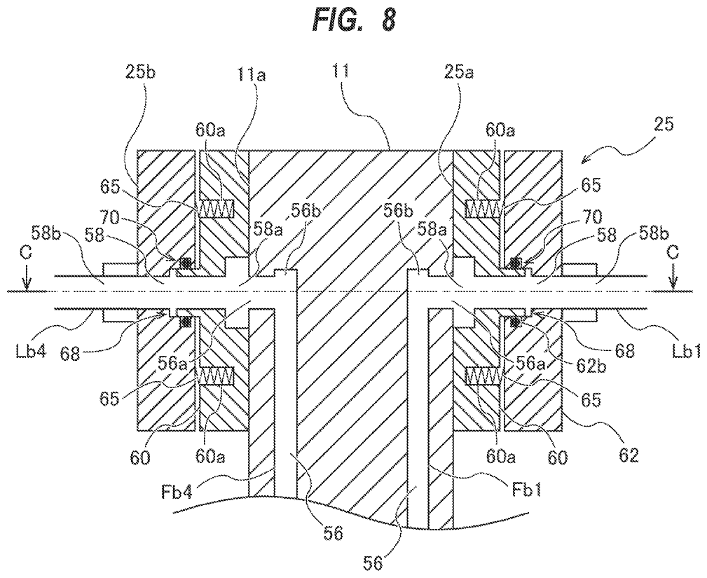

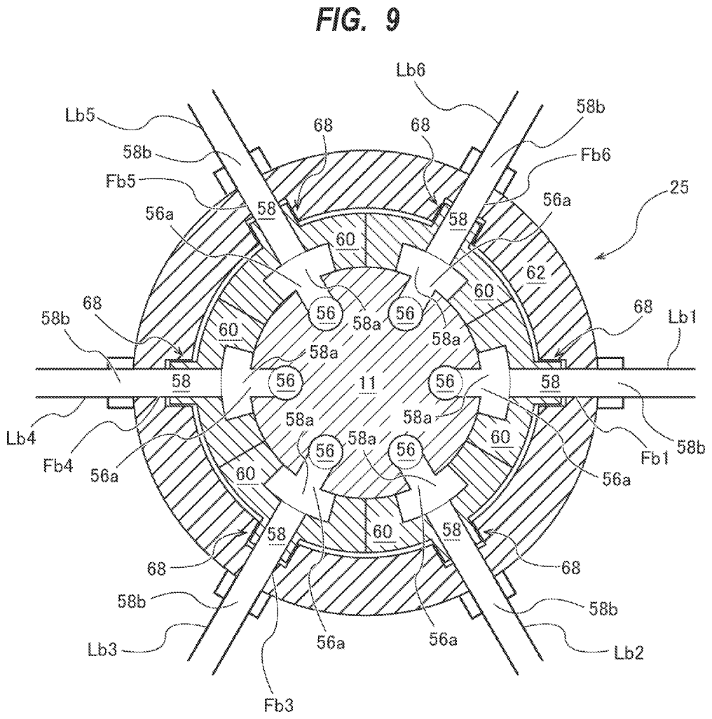

Next, configurations of the multi-path rotary joint 25 will be described. FIG. 7 is an exploded view showing an embodiment of the multi-path rotary joint 25. FIG. 8 is an enlarged cross-sectional view of the multi-path rotary joint 25 shown in FIG. 7. FIG. 9 is a cross-sectional view taken along line C-C of FIG. 8. The multi-path rotary joint 25 is arranged so as to surround at least a part of the head shaft 11. The multi-path rotary joint 25 has a plurality of (six in this embodiment) joint members 60 arranged along the circumferential direction of the head shaft 11, and a joint holder 62 arranged so as to surround these joint members 60. The number of joint members 60 corresponds to the number of fluid supply lines Lb1 to Lb6 coupled to the multi-path rotary joint 25. Each joint member 60 is an arc-shaped plate structure when viewed from above. The joint members 60 as a whole have a shape that is like a ring-shaped structure divided into six equal parts. The joint holder 62 is an annular structure.

The multi-path rotary joint 25 of this embodiment has six coupling ports 58b configured to be coupled to the six fluid supply lines Lb1 to Lb6, respectively. The fluid delivery lines Fb1 to Fb6 have six flow passages, respectively, including six shall flow-passages 56 formed in the head shaft 11 and six joint flow-passages 58 formed in the multi-path rotary joint 25. The six shall flow-passages 56 have six shaft openings 56a, respectively, which are open in the outer surface 11a of the head shaft 11. Each shaft flow-passage 56 further includes a bent portion 56b. The shaft flow-passage 56 extends upward along the axial direction of the head shaft 11 from the lower end of the head shaft 11, is bent at the bent portion 56b, and extends to the shall opening 56a. The plurality of shaft flow-passages 56 communicate with the pressure chambers Cb1 to Cb6, respectively.

The six joint flow-passages 58 have six joint openings 58a, being open in an inner surface 25a of the multi-path rotary joint 25, and six coupling ports 58b being open in an outer surface 25h of the multi-path rotary joint 25. The joint openings 58a face the shaft openings 56a, respectively. The six shaft openings 56a and the six joint openings 58a are arranged along the circumferential direction of the head shaft 11, and are located at the same position in the axial direction of the head shaft 11. The shaft flow-passages 56 communicate with the joint flow-passages 58 through the shaft openings 56a and the joint openings 58a. The fluid supply lines Lb1 to Lb6 are coupled to the multi-path rotary joint via the six coupling ports 58b, and communicate with the six joint flow-passages 58, respectively.

The multi-path rotary joint 25 is configured to allow each one of the fluid supply lines Lb1 to Lb6 to communicate with the six shaft flow-passages 56 one by one each time the head shaft 11 makes one revolution together with the polishing head 10. When the head shaft 11 is rotating, the multi-path rotary joint 25 and the fluid supply lines Lb1 to Lb6 do not rotate and their positions are fixed (i.e., remain stationary).

When the head shaft 11 rotates, the six shaft openings 56a move in the circumferential direction of the head shaft 11, so that each shaft opening 56a faces the joint opening 58a and the inner surface 25a of the multi-path rotary joint 25 alternately. Each shaft flow-passage 56 communicates with the joint flow-passage 58 when the shaft opening 56a faces the joint opening 58a corresponding to the joint flow-passage 58. Therefore, during rotating of the head shaft 11, the compressed fluid in the fluid supply lines Lb1 to Lb6 is sequentially supplied into the pressure chambers Cb1 to Cb6, as the fluid delivery lines Fb1 to Fb6 are switched from one to another to communicate with the fluid supply lines Lb1 to Lb successively. In other words, the compressed fluid is supplied into each of the pressure chambers Cb1 to Cb6 once from all the fluid supply lines Lb1 to Lb6 each time the head shaft 11 makes one revolution.

The six joint flow-passages 58 extend through the six joint members 60, respectively, and extend through the joint holder 62. The six joint openings 58a are open in inner surfaces of the six joint members 60, respectively. The six coupling ports 58b are open in an outer surface of the joint holder 62. As shown in FIG. 9, each joint opening 58a extends in the circumferential direction of the head shaft 11, and a width of each joint opening 58a is larger than a width of each shaft opening 56a. Thus, when the head shaft 11 rotates to sequentially switch the joint openings 58a facing each shaft opening 56a, a sufficient amount of time can be ensured for each shaft flow-passage 56 to communicate with the joint flow-passage 58. As a result, the compressed fluid can be sufficiently supplied into the pressure Chambers Cb1 to Cb6.

There may be a slight gap between the six joint members 60 and the joint holder 62. As shown in FIG. 7, each joint member 60 has a plurality of spring-holding holes 60a. The spring-holding holes 60a are formed in an outer surface of the joint member 60, and extend inwardly in the radial direction of the multi-path rotary joint 25. The spring-holding holes 60a do not penetrate the joint member 60.

The multi-path rotary joint 25 has springs 65 disposed in the spring-holding holes 60a, respectively. The springs 65 are configured to press the six joint members 60 against the head shaft 11 by their elastic forces. Thus, the six joint members 60 can be in tight contact with the head shaft 11, and as a result, leakage of the compressed fluid from the connection points between the shaft flow-passages 56 and the joint flow-passages 58 can be minimized. The plurality of joint members 60 and the head shaft 11 are made of hard material (e.g., ceramic, such as SiC, carbon, or metal such as stainless steel or aluminum).

The number of joint members 60 is not limited as long as each joint member 60 can be in tight contact with the head shaft 11, and may be less than six or more than six. For example, one joint member 60 may be provided for two joint flow-passages 58. In this embodiment, the four spring-holding holes 60a and the four springs 65 are provided for each joint member 60, while the number of spring-holding holes 60a and the number of springs 65 are not limited as long as each joint member 60 can be in tight contact with the head shaft 11, and may be less than four or more than four. In one example, one spring-holding hole 60a and one spring 65 may be provided for each joint member 60.

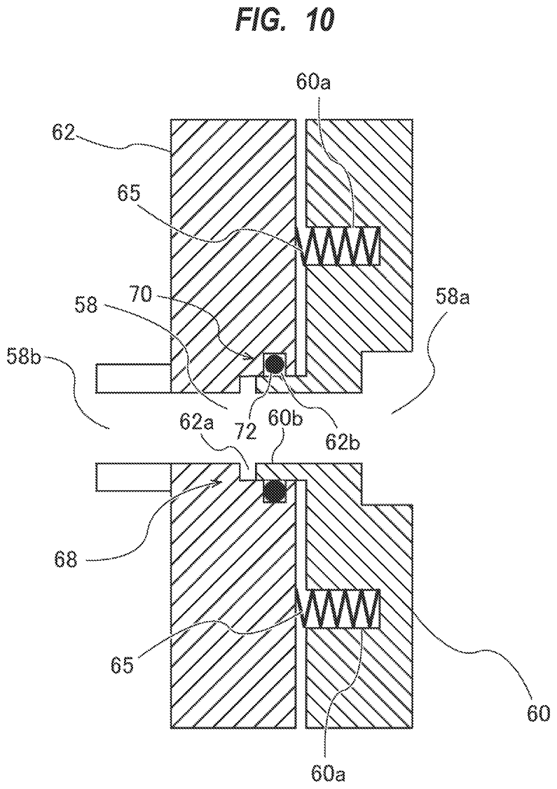

The multi-path rotary joint 25 has a plurality of (six in this embodiment) positioning mechanisms 68 configured to fix relative positions of the six joint members 60 with respect to the joint holder 62 in the circumferential direction of the six joint members 60. FIG. 10 is an enlarged cross-sectional view showing an embodiment of the positioning mechanism 68. The positioning mechanism 68 includes a protrusion 60b formed on the outer surface of each joint member 60, and a recess 62a formed in an inner surface of the joint holder 62. The joint flow-passage 58 extends through the protrusion 60b. The positioning mechanism 68 is configured to restrict movement of the joint member 60 in the circumferential direction with respect to the joint holder 62 by fitting the projection 60b of the joint member 60 into the recess 62a of the joint holder 62. On the other hand, the positioning mechanism 68 is configured to allow movement of the joint member 60 in the radial direction with respect to the joint holder 62.

Each of the six positioning mechanisms 68 has a seal mechanism 70 configured to seal a gap between an outer surface of the protrusions 60b of the joint member 60 and an inner surface of the recess 62a of the joint holder 62. Each seal mechanism 70 includes a seal groove 62b formed in the joint holder 62, and an endless seal member (e.g., an O-ring) 72. The seal groove 62b is formed in a surface forming the recess 62a. The endless seal member 72 is arranged in the seal groove 62b. The seal mechanism 70 seals the gap between the outer surface of the protrusion 60b and the inner surface of the recess 62a When the joint member 60 moves in the radial direction with respect to the joint holder 62, so that the seal mechanism 70 can prevent the compressed fluid from leaking from the joint flow-passage 58.

The configurations of the positioning mechanisms 68 are not limited to this embodiment as long as the relative positions of the six joint members 60 with respect to the joint holder 62 in the circumferential direction can be fixed. In one embodiment, each positioning mechanism 68 may include a recess formed in the joint member 60, and a protrusion formed on the joint holder 62. The configurations of each seal mechanism 70 are not limited to this embodiment as long as the seal mechanism 70 can seal the gap between the joint member 60 and the joint holder 62. In one embodiment, each seal mechanism 70 may include a seal groove formed in the joint member 60, and an endless seal member.

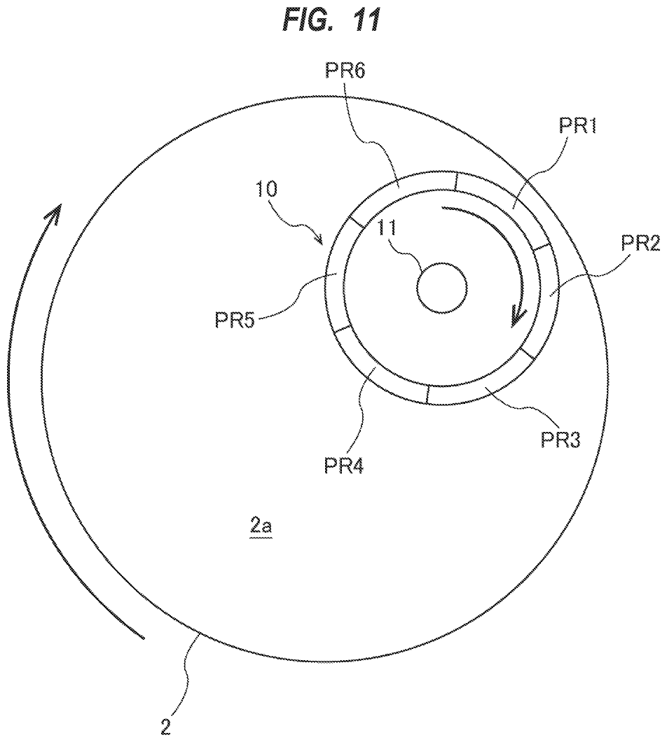

FIG. 11 is a diagram showing a plurality of pressure regions PR1 to PR6 indicating positions where the pressing forces generated by the plurality of pressure chambers Cb1 to Cb6, respectively, on a plurality of regions of the retainer ring 40 are switched. The pressure chambers Cb1 to Cb6 of the polishing head 10 are rotated with the rotation of the head shaft 11. Each of the pressure chambers Cb1 to Cb6 communicates with the fluid supply lines Lb1 to Lb6 one by one through the multi-path rotary joint 25 with the rotation of the head shaft 11. The plurality of pressure regions PR1 to PR6 correspond to positions of the fluid supply lines Lb1 to Lb6. Relative positions of the plurality of pressure regions PR1 to PR6 with respect to the polishing pad 2 are fixed. The plurality of pressure regions PR1 to PR6 do not rotate, while the pressure chambers Cb1 to Cb6 of the polishing head 10 rotate, Each of the plurality of pressure regions PR1 to PR6 has an arc shape when viewed from above.

A pressure chamber located in the pressure region PR1 shown in FIG. 11 communicates with the fluid supply line Lb1, a pressure chamber located in the pressure region PR2 communicates with the fluid supply line Lb2, a pressure chamber located in the pressure region PR3 communicates with the fluid supply line Lb3, a pressure Chamber located in the pressure region PR4 communicates with the fluid supply line Lb4, a pressure chamber located in the pressure region PR5 communicates with the fluid supply line Lb5, and a pressure chamber located in the pressure region PR6 communicates with the fluid supply line Lb6. The fluid supply lines are switched from one to another to communicate with the pressure chamber located in each of the pressure regions PR1 to PR6 with rotation of the polishing head 10 and the head shaft 11. The relative positions of the plurality of pressure regions PR1 to PR6 with respect to the polishing pad 2 may be adjusted by the pressure of the compressed fluid supplied from the fluid supply lines Lb1 to Lb6, a rotation speed of the polishing pad 2, a rotation speed of the polishing head 10 (i.e., the head shaft 11), etc.

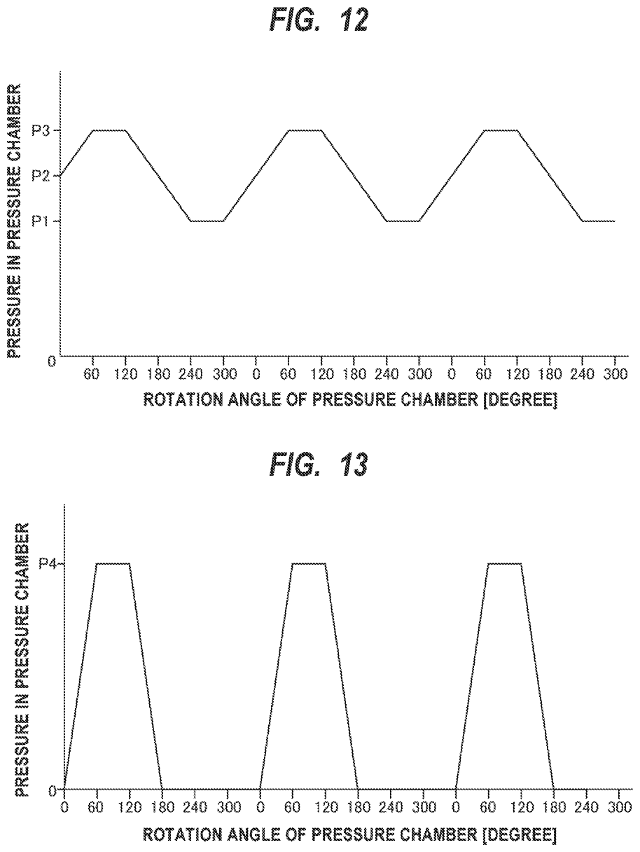

During polishing of the substrate W, the pressure regulators Rb1 to Rb6 basically operate to maintain constant set pressure values of the compressed fluid in the fluid supply lines Lb1 to Lb6, respectively. FIG. 12 is a graph showing an embodiment of change in pressure in the pressure chamber Cb1 with the rotation of the polishing head 10 (i.e., the head shaft 11). In FIG. 12, horizontal axis represents a rotation angle of the pressure chamber Cb1, and vertical axis represents a pressure in the pressure chamber Cb1. In this embodiment, the set pressure value of the compressed fluid in the fluid supply line Lb1 (i.e., the set pressure value in the pressure region PR1) is P2, the set pressure value of the compressed fluid in the fluid supply line (i.e., the set pressure value in the pressure region PR2) is P3 (>P2), the set pressure value of the compressed fluid in the fluid supply line Lb3 (i.e., the set pressure value in the pressure region PR3) is P3, the set pressure value of the compressed fluid in the fluid supply line Lb4 (i.e., the set pressure value in the pressure region PR4) is P2, the set pressure value of the compressed fluid in the fluid supply line Lb5 (i.e., the set pressure value in the pressure region PR5) is P1 (<P2), and the set pressure value of the compressed fluid in the fluid supply line Lb6 (i.e., the set pressure value in the pressure region PR6) is P1.

The pressure chamber Cb1 rotates in a direction indicated by an arrow in FIG. 11 with the rotation of the polishing head 10 and the head shaft 11. When the pressure chamber Cb1 is located in the pressure region PR1, the rotation angle of the pressure chamber Cb1 is 0 degrees. When the pressure chamber Cb1 is located in the pressure region PR2, the rotation angle of the pressure chamber Cb1 is 60 degrees. When the pressure chamber Cb1 is located in the pressure region PR3, the rotation angle of the pressure chamber Cb1 is 120 degrees. When the pressure chamber Cb1 is located in the pressure region PR4, the rotation angle of the pressure chamber Cb1 is 180 degrees. When the pressure chamber Cb1 is located in the pressure region PR5, the rotation angle of the pressure chamber Cb1 is 240 degrees. When the pressure chamber Cb1 is located in the pressure region PR6, the rotation angle of the pressure chamber Cb1 is 300 degrees. Therefore, the pressure in the pressure chamber Cb1 is P2 when the pressure chamber Cb1 is located in the pressure region PR1 (0 degrees). The pressure in the pressure chamber Cb1 is P3 when the pressure chamber Cb1 is located in the pressure region PR2 (60 degrees). The pressure in the pressure chamber Cb1 is P3 when the pressure chamber Cb1 is located in the pressure region PR3 (120 degrees). The pressure in the pressure chamber Cb1 is P2 when the pressure chamber Cb1 is located in the pressure region PR4 (180 degrees). The pressure in the pressure chamber Cb1 is P1 when the pressure chamber Cb1 is located in the pressure region PR5 (240 degrees). The pressure in the pressure chamber Cb1 is P1 when the pressure chamber Cb1 is located in the pressure region PR6 (300 degrees).

As shown in FIG. 12, the pressure in the pressure chamber Cb1 is sequentially switched between the set pressure values P1 to P3 of the compressed fluid in the fluid supply lines Lb1 to Lb6 each time the head shall 11 (i.e., the pressure chamber Cb1) makes one revolution. When the set pressure values of adjacent fluid supply lines are different, the pressure in the pressure chamber Cb1 changes gently. When the set pressure values of the adjacent fluid supply lines are the same, the pressure in the pressure chamber Cb1 is maintained at the set pressure value.

In the other pressure chambers Cb2 to Cb6, as well as the pressure chamber Cb1, the pressures in the pressure chambers Cb2 to Cb6 are sequentially switched between the set pressure values P1 to P3 of the compressed fluid in the fluid supply lines Lb1 to Lb6 each time the head shaft 11 (i.e., the pressure chambers Cb2 to Cb6) makes one revolution. In this manner, the six regions of the retainer ring 40 corresponding to the positions of the pressure chambers Cb1 to Cb6 can press the polishing surface 2a of the polishing pad 2 with a plurality of pressing forces corresponding to the pressures in the pressure chambers Cb1 to Cb6. As a result, the polishing rate at the edge portion of the substrate W can be precisely controlled. These pressing forces on the six regions of the retainer ring 40 include at least two different pressing forces. One of the at least two different pressing forces may be no pressure (i.e., the pressing force is 0) by establishing the fluid communication between the atmosphere and the fluid supply line(s) with the vent valve(s) attached to at least one of the fluid supply lines Lb1 to Lb6.

According to this embodiment, the polishing rate at the edge portion of the substrate W can be precisely controlled by using the multi-path rotary joint 25.

In this embodiment, the pressure regulators Rb1 to Rb6 regulate the pressures in the pressure chambers Cb1 to Cb6, respectively, such that the pressing forces generated by the pressure chambers located in the pressure regions PR2 and PR3 are larger than the pressing forces generated by the other pressure chambers. During polishing of the substrate W, the retainer ring 40 is subjected to a frictional force with the substrate W, so that the retainer ring 40 floats up at a downstream side in a rotating direction of the polishing pad 2 (i.e., the polishing surface 2a), i.e., a region corresponding to near the pressure regions PR2 and PR3 shown in FIG. 11. In contrast, the retainer ring 40 is sunk into the polishing pad 2 at an upstream side in the rotating direction of the polishing pad 2 (i.e., the polishing surface 2a). i.e., a region corresponding to near the pressure regions PR5 and PR6 shown in FIG. 11. Therefore, the pressing forces generated by the pressure chambers located at the downstream side in the rotating direction of the polishing pad 2 (i.e., the polishing surface 2a), i.e., located in the pressure regions PR2 and PR3, are set to be larger than the pressing forces generated by the other pressure chambers, so that a large pressing force can be applied to a downstream side of the retainer ring 40. As a result, the polishing rate at the edge portion of the substrate W can be effectively controlled.

Furthermore, during polishing of the substrate W, the substrate W is pressed against an inner circumferential surface of the retainer ring 40 due to the frictional force with the polishing surface 2a, so that a gap between the retainer ring 40 and the substrate W is minimized at the downstream side in the rotating direction of the polishing pad 2 (i.e., the polishing surface 2a). Therefore, the pressing forces generated by the pressure chambers located at the downstream side in the rotating direction of the polishing pad 2 (i.e., the polishing surface 2a), i.e., located in the pressure regions PR2 and PR3, are set to be larger than the pressing forces generated by the other pressure chambers, so that an influence of pad rebound can significantly be exerted on the substrate W.

FIG. 13 is a graph showing another embodiment of the change in pressure in the pressure chamber Cb1 with the rotation of the polishing head 10 (i.e., the head shaft 11). Configurations and operations of this embodiment, which will not be particularly described, are the same as those of the embodiment described with reference to FIG. 12, and duplicated descriptions will be omitted. In this embodiment, the set pressure value of the compressed fluid in the fluid supply line Lb1 (i.e., the set pressure value in the pressure region PR1) is 0, the set pressure value of the compressed fluid in the fluid supply line Lb2 (i.e., the set pressure value in the pressure region PR2) is P4, the set pressure value of the compressed fluid in the fluid supply line Lb3 (i.e., the set pressure value in the pressure region PR3) is P4, the set pressure value of the compressed fluid in the fluid supply line Lb4 (i.e., the pressure region PR4) is 0, the set pressure value of the compressed fluid in the fluid supply line Lb5 (i.e., the set pressure value in the pressure region PR5) is 0, and the set pressure value of the compressed fluid in the fluid supply line Lb6 (i.e., the set pressure value in the pressure region PR6) is 0.

The pressure in the pressure chamber Cb1 is 0 when the pressure Chamber Cb1 is located in the pressure region PR1 (0 degrees), The pressure in the pressure chamber Cb1 is P4 when the pressure chamber Cb1 is located in the pressure region PR2 (60 degrees). The pressure in the pressure chamber Cb1 is P4 when the pressure chamber Cb1 is located in the pressure region PR3 (120 degrees). The pressure in the pressure chamber Cb1 is 0 when the pressure chamber Cb1 is located in the pressure region PR4 (180 degrees). The pressure in the pressure chamber Cb1 is 0 when the pressure chamber Cb1 is located in the pressure region PR5 (240 degrees). The pressure in the pressure chamber Cb1 is 0 when the pressure chamber Cb1 is located in the pressure region PR6 (300 degrees). As shown in FIG. 13, the pressure in the pressure chamber Cb1 is sequentially switched between the set pressure values 0 and P4 of the compressed fluid in the fluid supply lines Lb1 to Lb6 each time the head shaft 11 (i.e., the pressure chamber Cb1) makes one revolution. In this embodiment, when the pressure chamber is located in the pressure region PR2 or PR3, the pressing force is generated on the retainer ring 40, and when the pressure chamber is located in another pressure region, no pressing force is generated on the retainer ring 40. Therefore, a larger difference in pressing force occurs between the downstream side and the upstream side of the retainer ring 40 in the rotating direction of the polishing pad 2 (i.e., the polishing surface 2a) as compared to the embodiment described with reference to FIG. 12.

In the embodiments described with reference to FIGS. 12 and 13, as examples, a large pressing force is applied to a portion of the retainer ring 40 located at the downstream side in the rotating direction of the polishing pad 2 (i.e., the polishing surface 2a). In the examples, the set pressure values of the compressed fluid in the fluid supply lines Lb2 and Lb3 (i.e., the set pressure values in the pressure regions PR2 and PR3) are set to be larger than the set pressure values of the compressed fluid in the other fluid supply lines. However, the set pressure values of the compressed fluid in the fluid supply lines Lb1 to Lb6 are not limited to these examples. In one embodiment, the set pressure values of the compressed fluid in the fluid supply lines Lb5 and Lb6 (i.e., the set pressure values in the pressure regions PR5 and PR6) may be set to be larger than the set pressure value of the compressed fluid in the other fluid supply lines such that a large pressing force is applied to a portion of the retainer ring 40 at the upstream side in the rotating direction of the polishing pad 2 (i.e., the polishing surface 2a).

In another embodiment, only the pressure regulator Rb3 among the pressure regulators Rb1 to Rb6 may be operated to maintain a constant set pressure value of the compressed fluid in the fluid supply line Lb3, and the fluid supply lines Lb1, Lb2, and Lb4 to Rb6 may communicate with the atmosphere by operating the vent valves coupled to the fluid supply lines Lb1, Lb2, and Lb4 to Rb6. In this embodiment, the pressing force is applied only to the region of the retainer ring 40 corresponding to the pressure area PR3, and no pressing force is applied to other regions of the retainer ring 40. In this way, when the pressing force is to be applied only to a region of the retainer ring 40 corresponding to a specific pressure region, the pressure regulator may be attached only to a specific fluid supply line among the plurality of fluid supply lines, and only the vent valves may be attached to the other fluid supply lines.

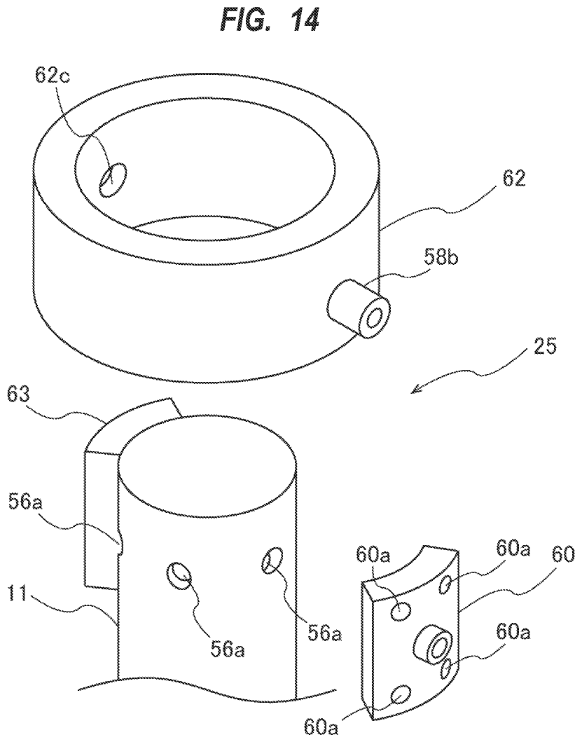

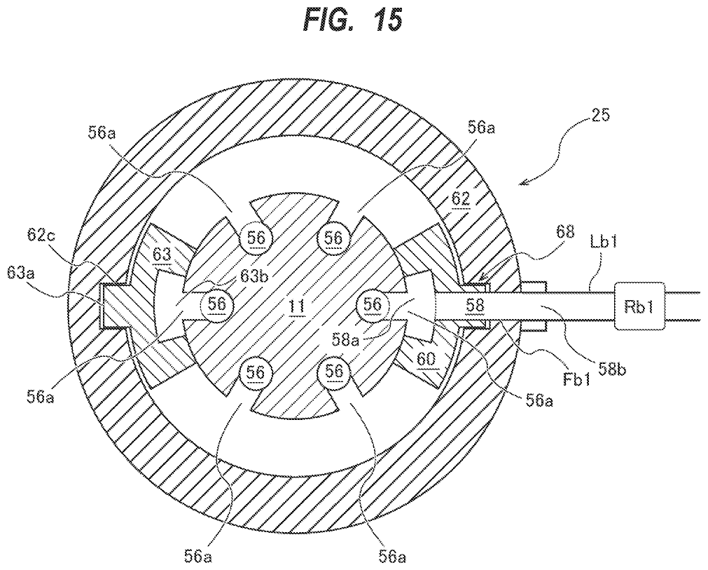

FIG. 14 is an exploded view showing another embodiment of the multi-path rotary joint 25. FIG. 15 is a cross-sectional view of the multi-path rotary joint 25 shown in FIG. 14. In this embodiment, as shown in FIGS. 14 and 15, the multi-path rotary joint 25 includes one joint member 60 and a joint holder 62, and the joint holder 62 has only one coupling port 58b. The polishing-head system 1 includes one fluid supply line Lb1, and one pressure regulator Rb1 attached to the fluid supply line Lb1. The fluid supply line Lb1 is coupled to the multi-path rotary joint 25 via the coupling port 58b.

The multi-path rotary joint 25 may include a spacer 63 located at the opposite side of the head shaft 11 from the joint member 60. The spacer 63 is arranged between the joint holder 62 and the head shaft 11. The joint member 60 and the spacer 63 are symmetrical with respect to the head shaft 11, As shown in FIG. 15, the spacer 63 has a protrusion 63a configured to fit into a recess 62c formed in the joint holder 62, and further has a through-hole 63b facing the shaft opening 56a. The protrusion 63a is fitted into the recess 62c of the joint holder 62, so that a position of the spacer 63 relative to the joint holder 62 in the circumferential direction is fixed.

The spacer 63 has a spring-holding hole (not shown). The spring-holding hole is formed in an outer surface of the spacer 63, and extends inwardly in the radial direction of the multi-path rotary joint 25, The spring-holding hole does not penetrate the spacer 63. The multi-path rotary joint 25 has a spring (not shown) disposed in the spring-holding hole. The spring is configured to press the spacer 63 against the head shaft 11 by its elastic force. Thus, the spacer 63 can be in tight contact with the head shaft 11 to stabilize a relative position of the head shaft 11 and the joint holder 62. As a result, the spacer 63 can stabilize a radial position of the joint member 60 with respect to the joint holder 62.

During rotating of the head shaft 11, each shaft flow-passage 56 communicates with the joint flow-passage 58 only when the shaft opening 56a faces the single joint opening 58a, and each shaft flow-passage 56 communicates with the atmosphere when the shaft opening 56a does not face the single joint opening 58a. Each shaft flow-passage 56 also communicates with the atmosphere when the shaft opening 56a faces the through-hole 63b of the spacer 63. Therefore, when the set pressure value of the compressed fluid in the fluid supply line Lb1 is maintained constant by the pressure regulator Rb1, a pressing force is applied only to a region of the retainer ring 40 corresponding to a specific pressure region. A plurality of pressing forces on the six regions of the retainer ring 40 include at least two different pressing forces. One of the at least two different pressing forces may be no pressure (i.e., the pressing force is 0) by establishing the fluid communication between the atmosphere and the shaft flow-passage 56. The multi-path rotary joint 25 of this embodiment has only one coupling port 58b, but can apply substantially two different pressing forces to the six regions of the retainer ring 40.

In one embodiment, the spacer 63 may be omitted. In this case also, during rotating of the head shaft 11, each shaft flow-passage 56 communicates with the joint flow-passage 58 only when the shaft flow-passage 56 faces the single joint opening 58a, while the other shaft fiord-passages 56 communicate with the atmosphere.

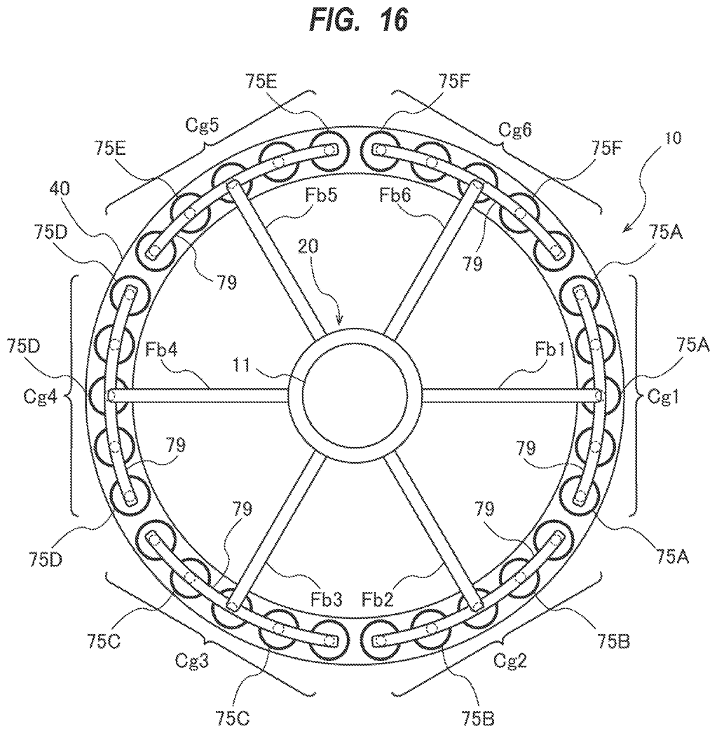

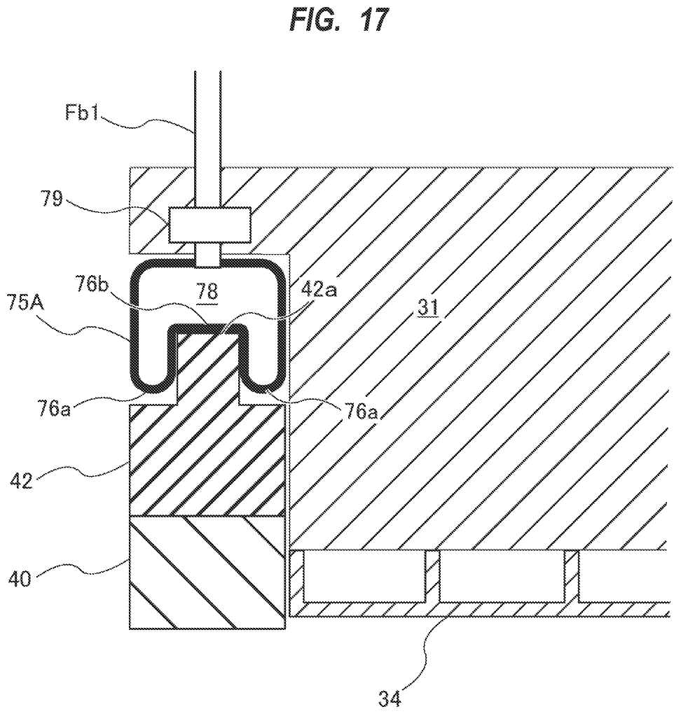

FIG. 16 is a schematic diagram showing another embodiment of the polishing head 10. Configurations and operations of this embodiment, which will not be particularly described, are the same as those of the above-mentioned embodiments, and duplicated descriptions will be omitted. FIG. 16 is a diagram of the polishing head 10 when viewed from above. The polishing head 10 of this embodiment includes a plurality of rolling diaphragms 75A to 75F instead of the plurality of retainer-ring pressing membranes 45A to 45F. A plurality of pressure chambers are formed inside these rolling diaphragms 75A to 75F.

In this embodiment, the plurality of pressure chambers formed by the rolling diaphragms 75A to 75F are divided into a plurality of pressure chamber groups Cg1 to Cg6. Specifically, a pressure chamber group Cg1 includes five pressure chambers formed by five rolling diaphragms 75A, a pressure chamber group Cg2 includes five pressure chambers formed by five rolling diaphragms 75B, a pressure chamber group Cg3 includes five pressure chambers formed by five rolling diaphragms 75C, a pressure chamber group Cg4 includes five pressure chambers formed by five rolling diaphragms 75D, a pressure chamber group Cg5 includes five pressure chambers formed by five rolling diaphragms 75E, and a pressure chamber group Cg6 includes five pressure chambers formed by five rolling diaphragms 75F. The thirty rolling diaphragms 75A to 75F are arranged along the circumferential direction of the retainer ring 40. Each of the rolling diaphragms 75A to 75F has a cylindrical shape.

The rolling diaphragms 75A to 75F are made of elastic material with excellent strength and durability, such as ethylene propylene rubber (EPDM), polyurethane rubber, or silicone rubber. In this embodiment, the polishing head 10 has the thirty rolling diaphragms 75A to 75F, and each of the pressure chamber groups Cg1 to Cg6 is formed by the five rolling diaphragms, while the present invention is not limited to this embodiment. In one embodiment, at least one pressure chamber belonging to one pressure chamber group may be formed by less than five rolling diaphragms or more than five rolling diaphragms.

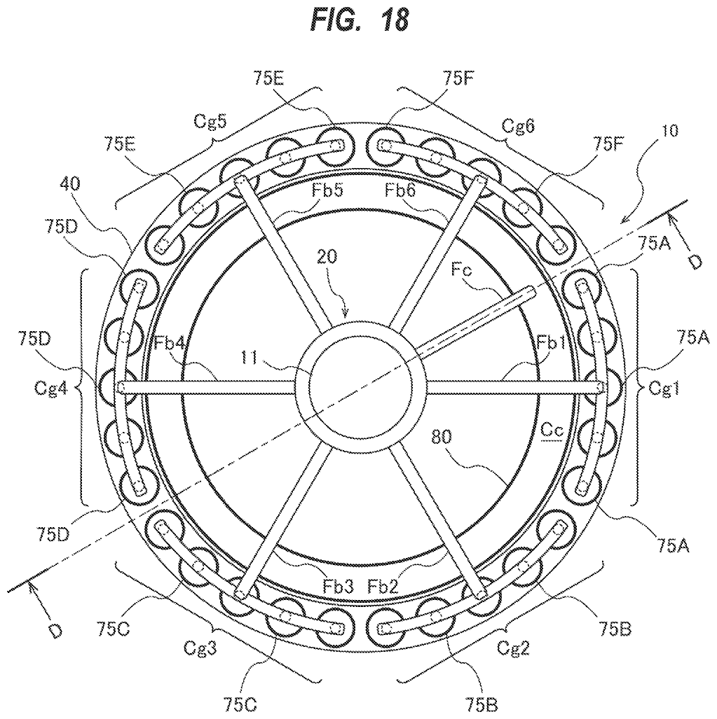

FIG. 17 is a cross-sectional view of the rolling diaphragm 75A shown in FIG. 16. Since configurations of the rolling diaphragms 75A to 75F are basically the same, a configuration of the rolling diaphragm 75A will be described below. The rolling diaphragm 75A includes roll portions 76a and a pressing portion 76b. A pressure chamber 78 is formed inside each rolling diaphragm 75A. The drive ring 42 has a raised portion 42a facing the pressing portion 76b of the rolling diaphragm 75A. The five rolling diaphragms 75A are coupled to the fluid delivery line Fb1. More specifically, the fluid delivery line Fb1 is coupled to the five rolling diaphragms 75A via a header 79 (see FIG. 16). The five rolling diaphragms 75A are coupled to the header 79.

When the compressed fluid is supplied into the pressure chambers 78 of the pressure chamber group Cg1 through the fluid delivery line Fb1, the pressing portions 76b of the five rolling diaphragms 75A are pushed downward to exert a pressing force against the raised portion 42a of the drive ring 42. This pressing force is applied to the retainer ring 40 via the drive ring 42. In this way, the pressure chamber group Cg1 generates the pressing force for pressing a region of the retainer ring 40 corresponding to a position of the pressure chamber group Cg1 against the polishing surface 2a of the polishing pad 2.

According to this embodiment, the compressed fluid in the pressure chambers 78 formed by the rolling diaphragms 75A to 75F efficiently acts as forces to expand the pressure chambers 78 downward with the configurations of the rolling diaphragms 75A to 75F each having the roll portions 76a and the pressing portion 76b, so that intended pressing forces can be generated by the rolling diaphragms 75A to 75F. The retainer ring 40 is worn due to friction with the polishing pad 2 as substrates are repeatedly polished. The configurations using the rolling diaphragms 75A to 75F can generate the intended pressing forces, especially even when the retainer ring 40 is worn due to the friction with the polishing pad 2.

FIG. 18 is a schematic diagram showing still another embodiment of the polishing head 10. Configurations and operations of this embodiment, which will not be particularly described, are the same as those of the embodiments described with reference to FIGS. 16 and 17, and duplicated descriptions will be omitted. FIG. 18 is a diagram of the polishing head 10 viewed from above. The polishing head 10 of this embodiment further includes ad annular pressure chamber Cc located adjacent to the plurality of pressure chamber groups Cg1 to Cg6. The polishing head 10 includes an annular rolling diaphragm 80 disposed inwardly of the plurality of rolling diaphragms 75A to 75F. An annular pressure chamber Cc is formed in the annular rolling diaphragm 80.

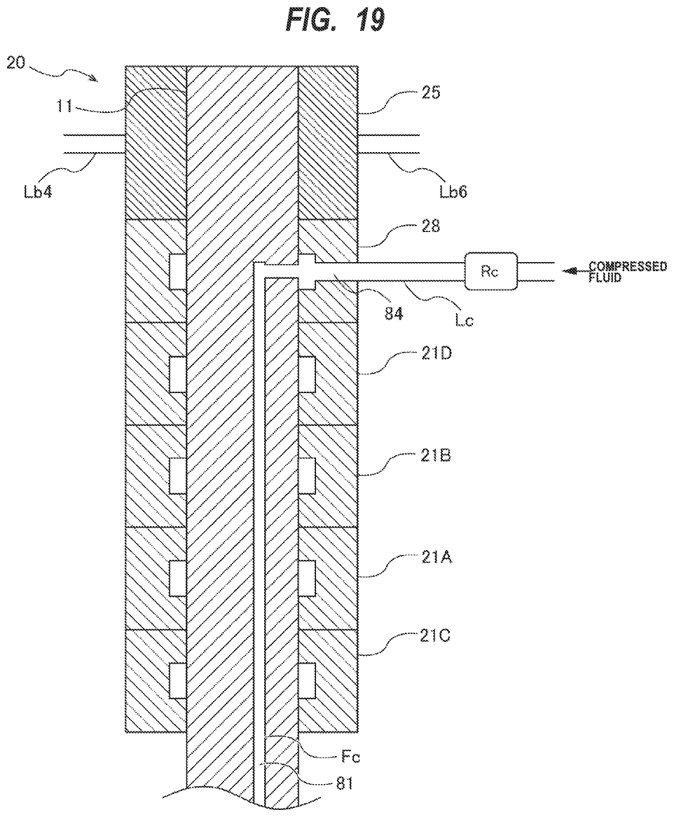

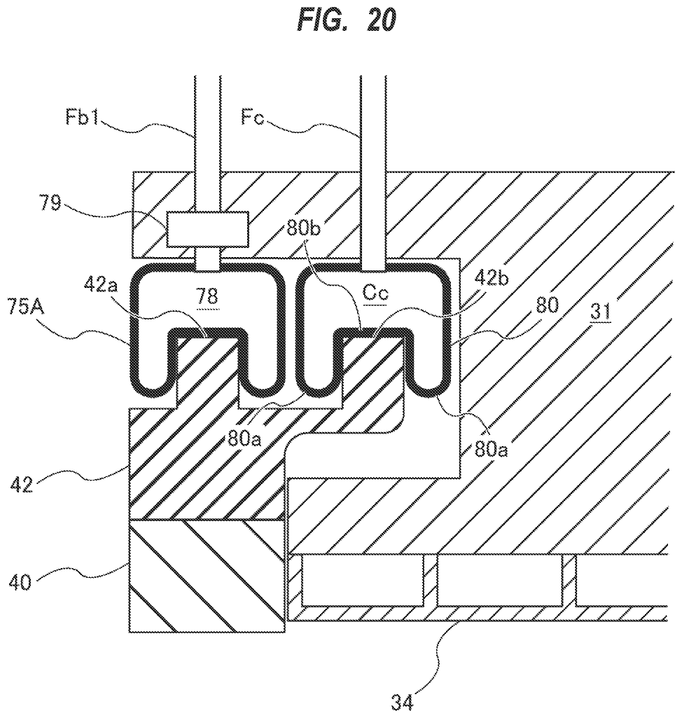

FIG. 19 is a cross-sectional view taken along line D-D of the rotary joint assembly shown in FIG. 18. The rotary joint assembly 20 of this embodiment further includes a rotary joint 28. The annular pressure chamber Cc is coupled to a fluid delivery line Fe. The fluid delivery line Fc extends in the carrier 31, the head shaft 11, and the rotary joint 28. The fluid delivery line Fc has flow passages including a shaft flow-passage 81 formed in the head shaft 11 and a joint flow-passage 84 formed in the rotary joint 28. The polishing-head system 1 includes a fluid supply line Lc coupled to the rotary joint 28, and a pressure regulator Rc attached to the fluid supply line Lc. The fluid delivery line Fc communicates with the fluid supply line Lc. One end of the fluid supply line Lc is coupled to a compressed-fluid supply source (not shown) which may be a utility supply source provided in the factory where the polishing apparatus is installed.

Configurations of the rotary joint 28, the shaft flow-passage 81, and the joint flow-passage 84 are the same as the configurations of the rotary joints 21A to 21D, the shaft flow-passage 51, and the joint flow-passage 54 described above, and duplicated descriptions thereof will be omitted.

Compressed fluid (e.g., compressed gas, such as compressed air) from the compressed-fluid supply source is supplied into the annular pressure chamber Cc through the fluid supply line Lc and the fluid delivery line Fc. The pressure regulator Re is configured to regulate a pressure of the compressed fluid in the annular pressure chamber Cc. The annular pressure chamber Cc generates a uniform pressing force for pressing the entire retainer ring 40 against the polishing surface 2a of the polishing pad 2. Thus, the pressing force on the retainer ring 40 against the polishing pad 2 can be adjusted.

The fluid supply lines Lc may be coupled to a vent valve (not shown). With this configuration, the annular pressure chamber Cc can communicate with the atmosphere when the vent valve is operated. The pressure regulator Re and the vent valve are coupled to the operation controller 9. The operation controller 9 transmits a target pressure value of the annular pressure chamber Cc to the pressure regulator Rc, so that the pressure regulator Rc operates such that the pressure in the annular pressure chamber Cc reaches the target pressure value.

FIG. 20 is a cross-sectional view of the rolling diaphragm 75A and the annular rolling diaphragm 80 shown in FIG. 18. The annular rolling diaphragm 80 includes roll portions 80a and a pressing portion 80b. The drive ring 42 further has a raised portion 42b facing the pressing portion 80b of the annular rolling diaphragm 80. The annular rolling diaphragm 80 is coupled to the fluid delivery line Fc. When the compressed fluid is supplied from the fluid supply line Lc into the annular pressure chamber Cc, the pressing portion 80b of the annular rolling diaphragm 80 is pushed downward to exert a pressing force on the raised portion 42b of the drive ring 42. This pressing force is applied to the retainer ring 40 via the drive ring 42. In this way, the annular pressure chamber Cc generates the pressing force for pressing the entire retainer ring 40 against the polishing surface 2a of the polishing pad 2 via the drive ring 42 located below the annular pressure chamber Cc.

According to this embodiment, the annular pressure chamber Cc applies the minimum necessary pressing force to the retainer ring 40 during polishing of the substrate W, while the plurality of rolling diaphragms 75A to 75F apply six pressing forces including at least two different pressing forces to six regions of the retainer ring 40 corresponding to the plurality of pressure chamber groups Cg1 to Cg6, respectively. As a result, the polishing rate at the edge portion of the substrate W can be precisely controlled.

In this embodiment, the annular rolling diaphragm 80 is arranged radially inwardly of the plurality of rolling diaphragms 75A to 75F, while in one embodiment, the annular rolling diaphragm 80 may be arranged radially outwardly of the plurality of rolling diaphragms 75A to 75F.

The annular rolling diaphragm 80 described with reference to FIGS. 18 to 20 can be applied to the embodiments described with reference to FIGS. 1 to 13. Specifically, the annular rolling diaphragm 80 may be arranged radially inwardly or radially outwardly of the plurality of retainer-ring pressing membranes 45A to 45F described above that form the plurality of pressure chambers Cb1 to Cb6.

As described with reference to FIGS. 12 and 13, the pressures in the pressure chambers Cb1 to Cb6 of the polishing head 10 change in accordance with the set pressure values of the compressed fluid in the fluid supply lines Lb1 to Lb6 with the rotation of the polishing head 10 (i.e., the head shaft 11). However, when the rotation speed of the polishing head 10 is fast, the pressures in the pressure chambers Cb1 to Cb6 of the polishing head 10 may not reach the set pressure values of the compressed fluid in the fluid supply lines Lb1 to Lb6.

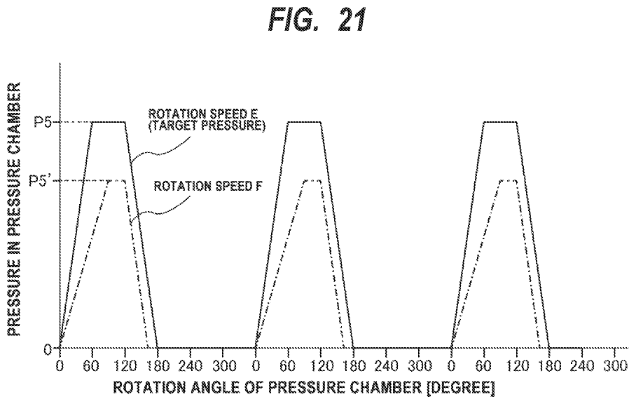

FIG. 21 is a graph illustrating difference in change in pressure in one pressure chamber Cb1 depending on the rotation speed of the polishing head 10. In FIG. 21, a graph indicated by solid line represents change in pressure in the one pressure chamber Cb1 When the polishing head 10 is rotated at a relatively low rotation speed E (e.g., 30 rpm). A graph indicated by dashed-dotted line represents change in pressure in the one pressure chamber Cb1 when the polishing head 10 is rotated at a relatively high rotation speed F (e.g., 90 rpm). In FIG. 21, the change in pressure in the pressure chamber Cb1 will be described, while changes in pressures in other pressure chambers Cb1 to Cb6 are the same as that of the pressure chamber Cb1.

In the example shown in FIG. 21, the set pressure value of the compressed fluid in the fluid supply line Lb1 (i.e., the set pressure value in the pressure region PR1) is 0, the set pressure value of the compressed fluid in the fluid supply line Lb2 (i.e., the set pressure value in the pressure region PR2) is P5, the set pressure value of the compressed fluid in the fluid supply line Lb3 (i.e., the set pressure value in the pressure region PR3) is P5, the set pressure value of the compressed fluid in the fluid supply line Lb4 (i.e., the set pressure value in the pressure region PR4) is 0, the set pressure value of the compressed fluid in the fluid supply line Lb5 (i.e., the set pressure value in the pressure region PR5) is 0, and the set pressure value of the compressed fluid in the fluid supply line Lb6 (i.e., the set pressure value in the pressure region PR6) is 0.

When the polishing head 10 is rotated at the relatively low rotation speed E, the pressure in the pressure chamber Cb1 is sequentially switched between the set pressure values 0 and P5 of the compressed fluid in the fluid supply lines Lb1 to Lb6 each time the polishing head 10 makes one revolution. More specifically, the pressure in the pressure chamber Cb1 is 0 when the pressure chamber Cb1 is located in the pressure region PR1 (0 degrees). The pressure in the pressure chamber Cb1 is P5 when the pressure chamber Cb1 is located in the pressure region PR2 (60 degrees). The pressure in the pressure chamber Cb1 is P5 when the pressure chamber Cb1 is located in the pressure region PR3 (120 degrees). The pressure in the pressure chamber Cb1 is 0 when the pressure chamber Cb1 is located in the pressure region PR4 (180 degrees). The pressure in the pressure chamber Cb1 is 0 when the pressure chamber Cb1 is located in the pressure region PR5 (240 degrees). The pressure in the pressure chamber Cb1 is 0 when the pressure chamber Cb1 is located at the pressure region PR6 (300 degrees). Changes in pressures in the other pressure chambers Cb2 to Cb6 are also the same as the change in pressure in the pressure chamber Cb1.

In this specification, “target pressures” are defined as the pressures (e.g., the above-described pressures of 0 and P5) in the pressure chambers Cb1 to Cb6 that are sequentially switched between the set pressure values of the compressed fluid in the fluid supply lines Lb1 to Lb6 communicating with each of the pressure chambers Cb1 to Cb6 when the polishing head 10 is rotated at the relatively low rotation speed E.

In contrast, when the polishing head 10 is rotated at the relatively high rotation speed F, a time during which the pressure Chamber Cb1 is located in each of the pressure regions PR1 to PR6 becomes shorter. Specifically, a time during which the pressure chamber Cb1 communicates with each of the fluid supply lines Lb1 to Lb6 becomes shorter, and as a result, a time during which the pressure chamber Cb1 communicates with the fluid supply lines Lb2 and Lb3 whose set pressure value of the compressed fluid is P5 becomes shorter. Therefore, the pressure in the pressure chamber Cb1 is increased only to a pressure P5′ that is smaller than P5 which is the set pressure value of the compressed fluid in the fluid supply line Lb1, when the pressure chamber Cb1 is located between the pressure region PR2 and the pressure region PR3, The changes in pressures in the other pressure chambers Cb1 to Cb6 are also the same as the change in pressure in the pressure chamber Cb1.

As described above, when the rotation speed of the polishing head 10 is relatively high, the pressures in the pressure chambers Cb1 to Cho may not reach the target pressures. As a result, the pressure chambers Cb1 to Cb6 cannot apply sufficient pressing forces to the retainer ring 40. Thus, in the embodiment described below, when the pressures in the pressure chambers Cb1 to Cb6 is smaller than the target pressures, the operation controller 9 is configured to transmit correcting set-pressure-values, which are larger than the set pressure values of the compressed fluid in the fluid supply lines Lb1 to Lb6, to the pressure regulators Rb1 to Rb6 to cause the pressure regulators Rb1 to Rb6 to correct the pressures in the pressure chambers Cb1 to Cb6.

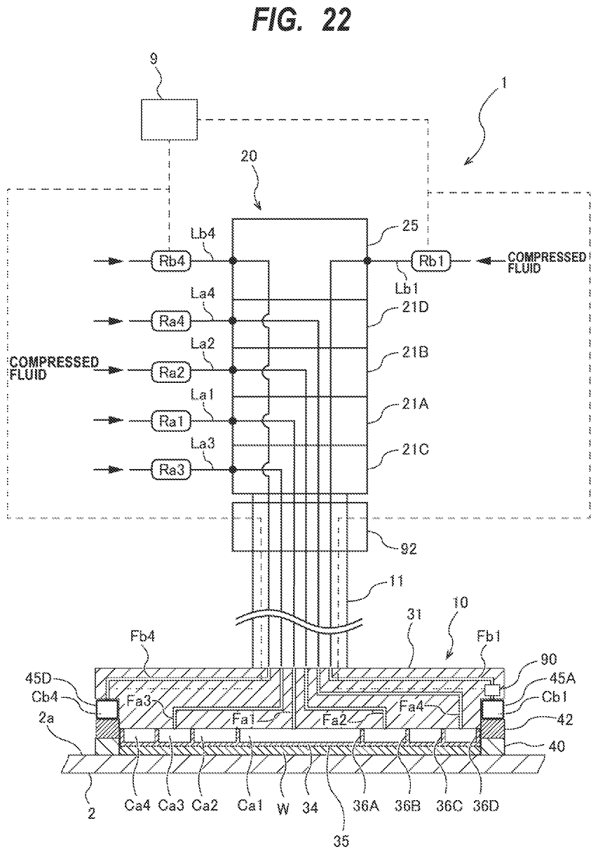

FIG. 22 is a cross-sectional view schematically showing another embodiment of the polishing-head system 1. Configurations and operations of this embodiment, which will not be particularly described, are the same as the configurations and the operations of the polishing-head system 1 described with reference to FIGS. 1 to 10, and duplicated descriptions will be omitted. In this embodiment, the polishing-head system 1 includes the operation controller 9. The polishing-head system 1 of this embodiment further includes at least one pressure sensor 90 configured to measure a pressure in at least one of the pressure chambers Cb1 to Cb6, and a rotary connector 92 configured to electrically couple the pressure sensor 90 to the operation controller 9. In this embodiment, the polishing-head system 1 includes the pressure sensor 90 configured to measure the pressure in the pressure chamber Cb1. In one embodiment, the polishing-head system 1 may include two or more pressure sensors 90 configured to measure the pressures in two or more of the pressure chambers Cb1 to Cb6. For example, the polishing-head system 1 may include six pressure sensors 90 configured to measure the pressures in the pressure chambers Cb1 to Cb6, respectively.

The pressure sensor 90 is attached to the fluid supply line Fb1, and is electrically coupled to the operation controller 9 via the rotary connector 92. The rotary connector 92 is attached to the head shaft 11. The pressure sensor 90 is configured to measure the pressure in the pressure chamber Cb1. A measurement value of the pressure in the pressure chamber Cb1 measured by the pressure sensor 90 is transmitted to the operation controller 9. The pressure sensor 90 is configured to transmit the measurement value of the pressure in the pressure chamber Cb1 to the operation controller 9 at predetermined time intervals. In one embodiment, the pressure sensor 90 may include a secondary battery (i.e., a battery), and a wireless communicating function for wirelessly communicating with the operation controller 9, and may be configured to be operable without using the rotary connector 92.

In this embodiment, as well as the example showing in FIG. 21, the set pressure values of the compressed fluid in the fluid supply lines Lb1, Lb4, Lb5, and Lb6 (i.e., the set pressure values in the pressure regions PR1, PR4, PR5, and PR6) are 0, and the set pressure values of the compressed fluid in the fluid supply lines Lb2 and Lb3 (i.e., the set pressure values in the pressure regions PR2 and PR3) are P5. The target pressure in this embodiment is 0 when the pressure chamber Cb1 is located in the pressure regions PR1 (0 degrees), PR4 (180 degrees), PR5 (240 degrees), and PR6 (300 degrees), and is P5 when the pressure chamber Cb1 is located in the pressure region PR2 (60 degrees) and PR3 (120 degrees).

When the measurement value of the pressure in the pressure chamber Cb1 transmitted from the pressure sensor 90 is smaller than the set pressure value, the operation controller 9 is configured to transmit the correcting set-pressure-values (which are larger than the set pressure values of the compressed fluid in the fluid supply lines Fb1 to Fb6) to the pressure regulators Rb1 to Rb6 to cause the pressure regulators Rb1 to Rb6 to correct the pressure in the pressure chamber Cb1 based on the correcting set-pressure-values. In this specification, “the correcting set pressure value is larger than the set pressure value” means that a correcting set-pressure-value of the compressed fluid in at least one of the fluid supply lines Lb1 to Lb6 is larger than the set pressure value. In this embodiment, the correcting set-pressure-values of the compressed fluid in the fluid supply lines Lb2 and Lb3 are larger than the set pressure values.

In this embodiment, the operation controller 9 transmits a correcting set-pressure-value 0, which is the same as the set pressure value 0, to the pressure regulators Rb1, Rb4, Rb5, and Rb6, and transmits a correcting set-pressure-value PC, which is larger than the set pressure value P5, to the pressure regulators Rb2 and Rb3. When the correcting set-pressure-value is transmitted from the operation controller 9 to the pressure regulators Rb1 to Rb6, the pressures of the compressed fluid in the fluid supply lines Lb1, Lb4, Lb5, and Lb6 (i.e., the pressure values in the pressure regions PR1, PR4, PR5, and PR6) become 0, and the pressures of the compressed fluid in the fluid supply lines Lb2 and Lb3 (i.e., the pressure values in the pressure regions PR2 and PR3) become the correcting set-pressure-value P6 which is larger than the set pressure value P5.

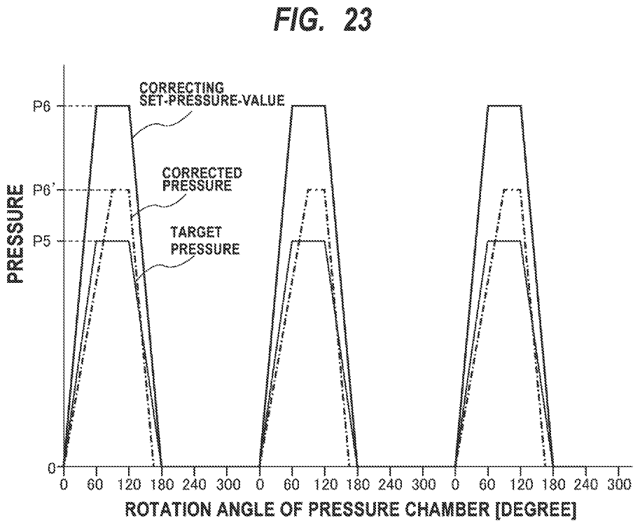

FIG. 23 is a graph showing an embodiment of the target pressures, the correcting set-pressure-values transmitted to the pressure regulators Rb1 to Rb6, and corrected pressures in the one pressure chamber Cb1. A graph indicated by thin-solid line in FIG. 23 represents change in target pressure in the one pressure chamber Cb1. A graph indicated by thick-solid line in FIG. 23 represents the correcting set-pressure-values. A graph shown by thick-dashed line in FIG. 23 represents change in pressure in the one pressure chamber Cb1 when the pressures of the compressed fluid in the fluid supply lines Lb1 to Lb6 are the correcting set-pressure-values. In other words, the graph indicated by the thick-dashed line represents change in pressure in the one pressure chamber Cb1 corrected by the operation controller 9.

The pressure in the pressure chamber Cb1 when the compressed fluid in the fluid supply line Lb1 is at the correcting set-pressure-value increases to a pressure P6′ that is smaller than P6, which is the correcting set-pressure-value of the compressed fluid in the fluid supply line Lb1. In this embodiment, the corrected pressure P6′ in the pressure chamber Cb1 when the pressure chamber Cb1 is located between the pressure regions PR2 and PR3 is larger than the target pressure P5 when the pressure chamber Cb1 is located between the pressure regions PR2 and PR3. The pressures in the other pressure chambers Cb1 to Cb6 are also corrected in the same manner as that of the pressure chamber Cb1.

The pressure sensor 90 is configured to measure the pressure in the pressure chamber Cb1. The measurement value of the pressure in the pressure chamber Cb1 measured by the pressure sensor 90 is transmitted to the operation controller 9. The operation controller 9 is configured to determine correcting set-pressure-values that minimize a difference between the pressure in the pressure chamber Cb1 measured by the pressure sensor 90 and the target pressure, and is configured to transmit the determined correcting set-pressure-values to the pressure regulators Rb1 to Rb6. In this manner, the operation controller 9 performs feedback control that determines the correcting set-pressure-values of the pressure regulators Rb1 to Rb6 based on the pressure in the pressure chamber Cb1 measured by the pressure sensor 90, so that the pressures in the pressure chambers Cb1 to Cb6 can be closer to the target pressures.

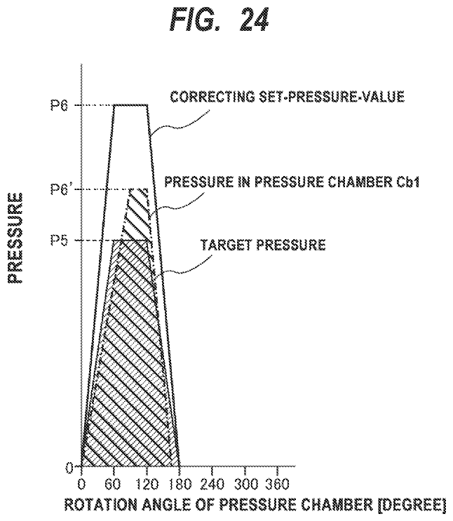

In one embodiment, the operation controller 9 is configured to determine correcting set-pressure-values that minimize a difference between an integral value of the pressure in the pressure chamber Cb1 during one revolution of the polishing head 10 and an integral value of the target pressure during one revolution of the polishing head 10. As shown in FIG. 24, an area of a region indicated by thin hatching represents the integral value of the target pressure during one revolution of the polishing head 10, and an area of a region indicated by thick hatching represents the integral value of the pressure in the pressure chamber Cb1 during one rotation of the polishing head 10. The operation controller 9 calculates the integral value of the pressure in the pressure chamber Cb1 during one revolution of the polishing head 10 and the integral value of the target pressure during one revolution of the polishing head 10, and determines correcting set-pressure-values that minimize the difference between these integral values.

The operation controller 9 transmits the correcting set-pressure-values that minimize the difference between the integral value of the pressure in the pressure chamber Cb1 during one revolution of the polishing head 10 and the integral value of the target pressure during one revolution of the polishing head 10 to the pressure regulators RN to Rb6 to thereby minimize a difference between the pressure in the pressure chamber Cb1 and the target pressure. Therefore, a difference between the pressing forces on the retainer ring generated by the pressure chambers Cb1 to Cb6 having the corrected pressures and the pressing forces on the retainer ring 40 generated by the pressure chambers Cb1 to Cb6 at the target pressures can be minimized. As a result, the pressure chambers Cb1 to Cb6 having the corrected pressures can apply sufficient pressing forces to the retainer ring 40.

In one embodiment, the operation controller 9 may be configured to determine the correcting set-pressure-values based on a correlation between set pressure values of the compressed fluid in the fluid supply lines Fb1 to Fb6 and the pressure in the pressure chamber Cb1. This correlation is obtained in advance. As described with reference to FIG. 21, there is a correlation between the set pressure values of the compressed fluid in the fluid supply lines Fb1 to Fb6 and the pressure in the pressure chamber al depending on the rotation speed of the polishing head 10. This correlation can be applied to the correlation between the correcting set-pressure-value and the corrected pressure in the pressure chamber Cb1.

The correlation between the set pressure values of the compressed fluid in the fluid supply lines Fb1 to Fhb and the pressure in the pressure chamber Cb1 is stored in advance in the memory 9a (see FIG. 1) of the operation controller 9. The operation controller 9 determines the correcting set-pressure-values that minimize the difference between the pressure the pressure in the pressure chamber Cb1 and the target pressure based on the correlation, which is stored in the memory 9a, between the set pressure values of the compressed fluid in the fluid supply lines Fb1 to Fb6 and the pressure in the pressure chamber Cb1. In this embodiment also, the corrected pressures in the pressure chambers Cb1 to Cb6 can apply sufficient pressing forces to the retainer ring 40.

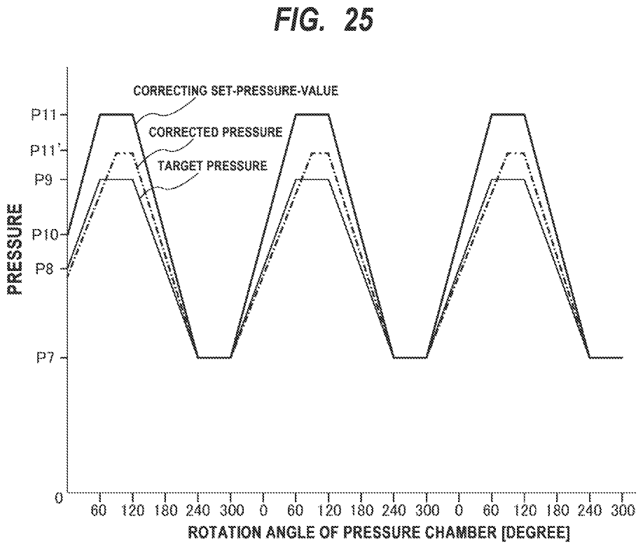

The set pressure values and the correcting set-pressure-values of this embodiment are an example, and the set pressure values and the correcting set-pressure-values are not limited to this embodiment. For example, as shown in FIG. 25, when the set pressure values of the compressed fluid in the fluid supply lines Lb1 and Lb4 (i.e., the set pressure values in the pressure regions PR1 and PR4) is P8, the set pressure values of the compressed fluid in the fluid supply lines Lb2 and Lb3 (i.e., the set pressure values in the pressure regions PR2 and PR3) is P9 (>P8), and the set pressure values of the compressed fluid in the fluid supply lines Lb5 and Lb6 (i.e., the set pressure values in the pressure regions PR5 and PR6) is P7 (<P8), the operation controller 9 may transmit a correcting set-pressure-value P10, which is larger than the set pressure value P8, to the pressure regulators Lb1 and Lb4, may transmit a correcting set-pressure-value P11, which is larger than the set pressure value P9, to the pressure regulators Rb2 and Rb3, and may transmit a correcting set-pressure-value P7, which is the same as the set pressure value, to the pressure regulators Lb5 and Lb6. In this embodiment, a corrected pressure P11′ in the pressure chamber Cb1 when the pressure chamber Cb1 is located between the pressure region PR2 and the pressure region PR3 is the larger than the target pressure P9 when the pressure chamber Cb1 is located between the pressure regions PR2 and PR3.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

1. A polishing-head system comprising:
a polishing head configured to press a substrate against a polishing surface;
a head shaft coupled to the polishing head;
a head rotating mechanism configured to rotate the polishing head together with the head shaft;
a multi-path rotary joint arranged around at least a part of the head shaft;
a fluid supply line coupled to the multi-path rotary joint; and
a pressure regulator attached to the fluid supply line,
wherein the polishing head has:
a substrate pressing surface configured to press the substrate against the polishing surface;
a retainer ring arranged around the substrate pressing surface; and
pressure chambers formed by elastic material and configured to generate pressing forces for pressing the retainer ring against the polishing surface,
the head shaft has shaft flow-passages communicating with the pressure chambers, respectively,
the multi-path rotary joint is configured to provide a communication between the fluid supply line and each one of the shaft flow-passages successively each time the head shaft makes one revolution, and
the pressure chambers are arranged along a circumferential direction of the retainer ring.

2. The polishing-head system according to claim 1, wherein
the shaft flow-passages have shaft openings being open in an outer surface of the head shaft,
the multi-path rotary joint has a joint flow-passage communicating with the fluid supply line,
the joint flow-passage has a joint opening being open in an inner surface of the multi-path rotary joint,
the shaft openings are arranged along a circumferential direction of the head shaft, and
the shaft openings and the joint opening are located at the same position in an axial direction of the head shaft.

3. The polishing-head system according to claim 2, wherein
the fluid supply line comprises fluid supply lines,
the pressure regulator comprises pressure regulators attached to the fluid supply lines, respectively,
the joint flow-passage comprises joint flow-passages communicating with the fluid supply lines, respectively, and
the joint opening comprises joint openings arranged along the circumferential direction of the head shaft.

4. The polishing-head system according to claim 24, wherein
the multi-path rotary joint has:
a joint member arranged along a circumferential direction of the head shaft;
a joint holder arranged around the joint member; and
a spring configured to press the joint member against the head shaft, and
the joint flow-passage extends through the joint member and the joint holder.

5. The polishing-head system according to claim 4, wherein the multi-path rotary joint has a positioning mechanism configured to fix a relative position of the joint member with respect to the joint holder in a circumferential direction of the joint member.

6. The polishing-head system according to claim 1, wherein
the pressure chambers comprise pressure chamber groups,
the pressure chamber groups communicate with the shaft flow-passages, respectively, and
each of the pressure chamber groups includes pressure chambers formed by rolling diaphragms, the rolling diaphragms being arranged along the circumferential direction of the retainer ring.

7. The polishing-head system according to claim 6, wherein each of the rolling diaphragms has a cylindrical shape.

8. The polishing-head system according to claim 1, wherein the polishing head further includes an annular pressure chamber located adjacent to the pressure chambers.

9. The polishing-head system according to claim 2, wherein a width of the joint opening is larger than a width of each of the shaft openings.

10. The polishing-head system according to claim 1, further comprising an operation controller configured to control an operation of the pressure regulator,
wherein the pressure chambers include a first pressure chamber,
the operation controller is configured to transmit a correcting set-pressure-value, which is larger than a set pressure value of fluid in the fluid supply line, to cause the pressure regulator to correct a pressure in the first pressure chamber when the pressure in the first pressure chamber is smaller than a target value.

11. The polishing-head system according to claim 10, wherein the operation controller is configured to determine the correcting set-pressure-value that minimizes a difference between an integral value of the pressure in the first pressure chamber during one revolution of the polishing head and an integral value of the target pressure during one revolution of the polishing head.

12. The polishing-head system according to claim 10, further comprising a pressure sensor configured to measure the pressure in the first pressure chamber,
wherein the operation controller is configured to determine the correcting set-pressure-value that minimizes a difference between the pressure in the first pressure chamber measured by the pressure sensor and the target pressure.

13. The polishing-head system according to claim 10, wherein the operation controller is configured to determine the correcting set-pressure-value that minimizes a difference between the pressure in the first pressure chamber and the target pressure based on a correlation, which is obtained in advance, between the set pressure value and the pressure in the first pressure chamber.

14. A polishing method for a substrate with the polishing-head system according to claim 1, comprising:
pressing the substrate against the polishing surface while rotating the substrate to polish the substrate; and
during polishing of the substrate, applying pressing forces to the retainer ring to press the retainer ring against the polishing surface by supplying fluid into the pressure chambers through the fluid supply line while providing a communication between the fluid supply line and each one of the shaft flow-passages successively,
wherein the pressing forces include at least two different pressing forces.

15. The polishing method according to claim 14, wherein
polishing of the substrate is performed while rotating the polishing surface, and
the polishing method comprises regulating pressures in the pressure chambers by the pressure regulator such that a pressing force generated by a pressure chamber, which is one of the pressure chambers, located at a downstream side in a rotating direction of the polishing surface is larger than a pressing force generated by other pressure chamber.

16. The polishing method according to claim 14, further comprising causing the pressure regulator to correct a pressure in a first pressure chamber of the pressure chambers based on a correcting set-pressure-value, which is larger than a set pressure value of the fluid in the fluid supply line, when the pressure in the first pressure chamber is smaller than a target pressure.

17. The polishing method according to claim 16, further comprising determining the correcting set-pressure-value that minimizes a difference between an integral value of the pressure in the first pressure chamber during one revolution of the polishing head and an integral value of the target pressure during one revolution of the polishing head.

18. The polishing method according to claim 16, further comprising:
measuring the pressure in the first pressure chamber; and
determining the correcting set-pressure-value that minimizes a difference between the pressure in the first pressure chamber measured by the pressure sensor and the target pressure.

19. The polishing method according to claim 16, further comprising determining the correcting set-pressure-value that minimizes a difference between the pressure in the first pressure chamber and the target pressure based on a correlation, which is obtained in advance, between the set pressure value and the pressure in the first pressure chamber.
